(19) United States
(12) Patent Application Publication
(10) Pub. No.: US 2026/0139368 A1
(43) Pub. Date: May 21, 2026

(54) TRANSITION METAL DICHALCOGENIDE HAVING A HETEROSTRUCTURE, METHOD FOR MANUFACTURING THE SAME, AND PHOTOELECTRIC DEVICE INCLUDING THE SAME

(71) Applicant: UIF (University Industry Foundation), Yonsei University, Seoul (KR)

(72) Inventors: Sang-Yong JU, Gyeonggi-do (KR); Dong Hwan Kim, Daejeon (KR); Yoonbeen Kang, Seoul (KR)

(73) Assignee: UIF (University Industry Foundation), Yonsei University, Seoul (KR)

(21) Appl. No.: 19/393,071

(22) Filed: Nov. 18, 2025

(30) Foreign Application Priority Data
Nov. 19, 2024 (KR) 10-2024-0165414

(51) Int. Cl. C23C 16/40; C23C 16/02; C23C 16/56; G03F 7/16

(52) U.S. Cl. CPC C23C 16/405; C23C 16/0236; C23C 16/0272; C23C 16/56; G03F 7/162

(57) ABSTRACT

The present invention relates to a transition metal dichalcogenide having a heterostructure, a method for manufacturing the same, and a photoelectric device including the same. More specifically, the method for manufacturing a transition metal dichalcogenide having a heterostructure of the present invention can form a uniformly, evenly, and continuously grown transition metal dichalcogenide having a heterostructure through hydrophilic treatment of a substrate, pH control of a transition metal precursor solution, and mixing of sodium cholate. Furthermore, by controlling the concentration of the transition metal precursor, it is possible to manufacture hierarchical transition metal dichalcogenides, which exhibit excellent reproducibility and can be applied to photoelectric devices.

### CROSS-REFERENCE TO RELATED APPLICATIONS

This application claims priority to Korean Patent Application No. 10-2024-0165414, filed on Nov. 19, 2024, and all the benefits accruing therefrom under 35 U.S.C. § 119, the contents of which in its entirety are herein incorporated by reference.

### BACKGROUND

### 1. Field

The present invention relates to a transition metal dichalcogenide having a heterostructure, a method for manufacturing the same, and a photoelectric device including the same.

### 2. Description of Related Art

The development of transition metal dichalcogenides (TMC) heterostructures is essential in advanced optoelectronic applications such as field-effect transistors, spintronics, and photocatalysts. Due to their unique optoelectronic properties, heterostructures generated by a combination of TMCs having various band gaps (1 to 2 eV) and relative band offsets are advantageous, enabling the control of optoelectronic properties by creating various heterostructure band gap types (type I, II, III). To realize large-area, high-quality TMC heterostructures, precise control over the growth process is required, and in particular, it is important to form defect-free heterostructures at specific sizes and locations. Chemical vapor deposition (CVD) is an important method for forming defect-free heterostructures, using metal and chalcogen precursors.

Furthermore, the creation of stacked heterostructures has been achieved through various state-of-the-art transfer methods, carried out using large-area TMCs grown by CVD with precise alignment and rotation. Spatially separated excitons and superconductivity phenomena occurring in twisted bilayer graphene at magic angles can be observed in stacked 2D heterostructures. On the other hand, in-plane TMC heterostructures have limitations due to the lack of growth methods compatible with conventional photolithography, despite continuous or sequential CVD growth methods. In particular, in-plane heterostructures cannot be obtained from exfoliated TMCs, and a growth method is essential.

### SUMMARY

In order to solve the above problems, an object of the present invention is to provide a method for manufacturing a transition metal dichalcogenide having a uniformly and continuously grown heterostructure through hydrophilic treatment of a substrate, pH control of a transition metal precursor solution, and mixing of sodium cholate.

Another object of the present invention is to provide a transition metal dichalcogenide having a heterostructure.

Another object of the present invention is to provide a photoelectric device including the transition metal dichalcogenide having a heterostructure of the present invention.

Another object of the present invention is to provide an optoelectronic device including the photoelectric device of the present invention.

The present invention provides a method for manufacturing a transition metal dichalcogenide having a heterostructure, comprising: forming a photoresist (PR) pattern on a substrate on which a first transition metal dichalcogenide (TMC) film is formed; and forming a second transition metal dichalcogenide (TMC) film on the substrate on which the PR pattern is formed.

The present invention also provides a transition metal dichalcogenide having a heterostructure, comprising: a substrate; and a transition metal dichalcogenide formed on the substrate, wherein the transition metal dichalcogenide is composed of a heterostructure in which a second transition metal dichalcogenide is inserted in a pattern into a first transition metal dichalcogenide in the plane of the substrate.

Furthermore, the present invention provides a photoelectric device including the transition metal dichalcogenide having a heterostructure of the present invention.

Furthermore, the present invention provides an optoelectronic device including the photoelectric device of the present invention.

The method for manufacturing a transition metal dichalcogenide having a heterostructure according to the present invention can form a uniformly, evenly, and continuously grown transition metal dichalcogenide heterostructure through hydrophilic treatment of a substrate, pH control of a transition metal precursor solution, and mixing of sodium cholate. Furthermore, by controlling the concentration of the transition metal precursor, it is possible to manufacture hierarchical transition metal dichalcogenides, which exhibit excellent reproducibility and can be applied to photoelectric devices.

The effects of the present invention are not limited to the effects mentioned above. It should be understood that the effects of the present invention include all effects inferable from the description below.

### BRIEF DESCRIPTION OF THE DRAWINGS

FIG. 1 is a schematic diagram illustrating a method for manufacturing a transition metal chalcogenide having a heterostructure according to the present invention.

FIGS. 2A to 2J are AFM surface morphology images of spin-coated MoO₃/SC solutions at different pH values in Example 1 of the present invention.

FIG. 3A is a Zeta (ζ) potential graph and FIG. 3B is a Raman spectrum graph of CVD grown MoO₃/SC solutions according to pH (2.4, 4.2, 5.3, 10.3, and 12.8) in Example 1 of the present invention.

FIGS. 4A to 4C are spin-coated AFM images of a 6 mM Na₂MoO₄ solution in Example 1 of the present invention.

FIG. 5A to 5E are optical images (FIG. 5A) of a MoS₂ film grown by CVD with a hydrophilic pattern, a comparison of water contact angles (FIG. 5B) of an O₂ plasma-treated substrate (top) and an untreated substrate (bottom), a high-magnification optical image of the O₂ plasma-treated region (FIG. 5C) and the untreated region (FIG. 5D), and an offset Raman spectrum (FIG. 5E) graph of the O₂ plasma-treated region (top) and the untreated region (bottom), in Example 1 of the present invention. The Raman spectrum was decomposed through Lorentz fitting. Experimental data are indicated by empty circles, and the red curve represents the sum of each Lorentz peak.

FIGS. 6A to 6R show AFM images of adsorbates in spin-coated MoO₃/SC solution (FIGS. 6A to 6D), AFM images of grown MoS₂ films (FIGS. 6E to 6H), AFM images of water-treated MoS₂ films at increasing MoO₃ concentrations (4, 6, 8, and 10 mM) (FIGS. 6I to 6L), an adsorbate density (V) graph (FIG. 6M) based on critical height counting at 4 nm according to MoO₃ concentration, a sodium particle density (V) graph (FIG. 6N) according to MoO₃ concentration, the <R> tendency (FIG. 6O) of adsorbates and water-treated MoS₂ films as a function of MoO₃ concentration, the normalized offset Raman spectrum (FIG. 6P) of water-treated MoS₂ films with respect to the 520.8 cm⁻¹ Si band at different MoO₃ concentrations, the positions and peak separation graph (FIG. 6Q) of the E12g and A1g bands according to MoO₃ concentration, and the PL spectrum graph (FIG. 6R) of water-treated MoS₂ films at different MoO₃ concentrations, in Example 1 of the present invention.

FIGS. 7A to 7K show grown MoS₂ (FIGS. 7A to 7D) and AFM surface morphology images of isopropanol (IPA)-treated grown MoS₂ films (FIGS. 7E to 7H), the normalized offset Raman spectrum graph (FIG. 7I) of grown MoS₂ films derived from precursor deposits at increasing MoO₃ concentrations (4, 6, 8, 10 mM), the spectrum graph (FIG. 7J) of subsequently IPA-treated MoS₂ films, and the graph (FIG. 7K) of the positions and peak separation of the E12g and A1g bands according to different MoO₃ concentrations, in Example 1 of the present invention.

FIGS. 8A to 8G show, in Example 1 of the present invention: (FIG. 8A) an AFM image of a scratched film; (FIG. 8B) a HAADF-STEM image of a polycrystalline film where Moire patterns are indicated by white arrows (inset: FFT diffraction pattern showing five sets of hexagonal patterns); (FIG. 8C) a color code representation of polycrystals based on five different crystal directions (identifying BL and TL regions with distinct Moire patterns and representing the SL region); (FIG. 8D) a HAADF-STEM image showing grain boundaries with (6|4)-(7|5) defects; (FIG. 8E) an AFM image showing the formation of triangular crystals through steam and sulfur vaporization treatment of the continuous film at (inset: close-up view); (FIG. 8F) a real-time Raman spectrum graph of the corresponding film at; and (FIG. 8G) a size distribution analysis graph (inset: angular distribution of triangular MoS₂) of steam and sulfur-treated triangular crystals.

FIGS. 9A to 9K show (FIG. 9A) a schematic diagram of the process for generating an in-plane heterostructure using photolithography and CVD growth, (FIGS. 9B, 9D, 9F, 9H and 9J) optical images corresponding to each step described in (FIG. 9A), and (FIGS. 9C, 9E, 9G, 9I and 9K) AFM images showing the progress of each step described in (FIG. 9A) (white lines indicate height profiles marked along symmetrical triangle pairs in each figure), in Example 1 of the present invention.

FIGS. 10A to 10F show (FIG. 10A) an AFM surface morphology image of the grain boundary region of the in-plane heterostructure formed through photolithography and repetitive CVD processes (inset: optical image of the heterostructure on the substrate, and the height profile is indicated by white lines marked along opposing triangle pairs in (FIG. 10A)), (FIG. 10B) a Raman intensity map (the upper part shows the 408.4 cm⁻¹ peak corresponding to the A1g band of MoS₂, and the lower part shows the 354.4 cm⁻¹ peak corresponding to the 2LA band of WS₂, pixel size: 1 μm²), (FIG. 10C) a series of Raman spectrum graphs measured across the interface marked in (FIG. 10B), (FIG. 10D) a TEM image near the interface of the heterostructure (the white line highlights the continuous zigzag surface traversing the heterostructure, the two arrows indicate the direction of ϵ, and the inset is the FFT diffraction pattern), (FIG. 10E) a HAADF-STEM image of the interface, and (FIG. 10F) a HAADF-STEM profile measured along the line in (FIG. 10E) (indicating the BL WS₂—MoS₂ heterostructure, where “W|2S” or “Mo|2S” represents the intensity resulting from the overlap of W and 2S, or Mo and 2S, respectively), in Example 1 of the present invention.

### DETAILED DESCRIPTION

Hereinafter, the present invention will be described in more detail with reference to one embodiment.

The present invention relates to a transition metal dichalcogenide having a heterostructure, a method for manufacturing the same, and a photoelectric device including the same.

As described above, hierarchical heterostructures composed of transition metal dichalcogenides (TMCs) configured with specific junctions are essential for advancing next-generation optoelectronic devices. However, unlike stacked structures, developing in-plane TMC heterostructures at desired junctions has been limited.

Accordingly, the present inventors found that a uniformly, evenly, and continuously grown transition metal dichalcogenide heterostructure can be formed by hydrophilic treatment of a substrate, pH control of a transition metal precursor solution, and mixing of sodium cholate, thereby completing the present invention. Furthermore, by controlling the concentration of the transition metal precursor, it is possible to manufacture hierarchical transition metal dichalcogenides, which exhibit excellent reproducibility and can be applied to photoelectric devices.

Specifically, the present invention provides a method for manufacturing a transition metal dichalcogenide having a heterostructure, comprising: forming a photoresist (PR) pattern on a substrate on which a first transition metal dichalcogenide (TMC) film is formed; and forming a second transition metal dichalcogenide (TMC) film on the substrate on which the PR pattern is formed; thereby providing a method for manufacturing a transition metal dichalcogenide having a heterostructure.

The step of forming the photoresist (PR) pattern may be performed by a process including the following steps (A) to (E), wherein the steps (A) to (E) are: (A) hydrophilically treating the substrate surface; (B) performing first spin coating of a pH-controlled first transition metal precursor solution including a first transition metal precursor and alkali metal cholate (e.g., sodium cholate (SC) on the hydrophilically treated substrate; (C) performing first CVD coating of the first spin-coated substrate under sulfur and argon gas to form a first transition metal dichalcogenide (TMC) film; (D) removing sodium particles on the substrate; and (E) forming a photoresist (PR) pattern on the sodium-removed substrate.

The step of forming the second transition metal dichalcogenide (TMC) film is performed by a process including the following steps (F) to (J), wherein the steps (F) to (J) are: (F) exposing the hydrophilically treated surface of the region of the substrate where the PR pattern is not formed by reactive ion etching (RIE) of the substrate on which the PR pattern is formed; (G) performing second spin coating of a pH-controlled second transition metal precursor solution including a second transition metal precursor and alkali metal cholate (e.g., sodium cholate (SC) on the substrate; (H) removing the PR pattern of the second spin-coated substrate; (I) performing second CVD coating of the PR pattern-removed substrate under sulfur and argon gas to form a second transition metal dichalcogenide (TMC) film; and (J) removing sodium particles on the substrate.

Hereinafter, each step will be described in detail.

### (A) Step of Hydrophilically Treating the Substrate Surface

The step (A) may hydrophilically treat the substrate surface to ensure uniform spin coating of the first and second transition metal precursor solutions and even growth of the transition metal dichalcogenide on the substrate. That is, when the substrate surface is hydrophilically treated, the first and second transition metal precursor solutions can be effectively adsorbed onto the substrate, allowing for the growth of uniform and even first and second TMC films, thereby further improving the quality.

Conversely, if the substrate surface is not hydrophilically treated, adsorption may be non-uniform, resulting in significant degradation of film quality, and if it is hydrophobically treated, it may lead to particle aggregation, making uniform growth difficult.

The substrate may be SiO₂/Si, and may have a thickness of 250 to 310 nm. Preferably, the substrate may have a thickness of 260 to 300 nm, and most preferably 280 to 290 nm.

The hydrophilic treatment may be O₂ plasma treatment.

The O₂ plasma treatment may be performed at 80 to 120 W for 5 to 9 minutes, preferably at 85 to 115 W for 6 to 8 minutes, and most preferably at 90 to 110 W for 6 to 7 minutes.

(B) Step of Performing First Spin Coating of a pH-Controlled First Transition Metal Precursor Solution Including a First Transition Metal Precursor and Alkali Metal Cholate (e.g., Sodium Cholate (SC) on the Substrate

In step (B), the pH-controlled first transition metal precursor solution and the silanol groups on the substrate may be first spin-coated through hydrogen bonding while minimizing moisture exposure on the hydrophilically treated substrate. In particular, in step (B), moisture acts as an interfering factor, which may weaken the binding force between precursors and degrade the quality of the final product, thus minimizing moisture exposure is important.

The first transition metal precursor solution may include 98.5 to 99.9 wt % of the first transition metal precursor and 0.1 to 1.5 wt % of alkali metal cholate (e.g., sodium cholate (SC), preferably 98.7 to 99.4 wt % of the first transition metal precursor and 0.6 to 1.3 wt % of alkali metal cholate (e.g., sodium cholate (SC), and most preferably 98.9 to 99.1 wt % of the first transition metal precursor and 0.9 to 1.1 wt % of alkali metal cholate (e.g., sodium cholate (SC).

In particular, the alkali metal cholate (e.g., sodium cholate (SC) can quickly convert the first transition metal precursor into the first transition metal dichalcogenide, and can act as a reproducible catalyst. That is, the alkali metal cholate (e.g., sodium cholate (SC) can precipitate the first transition metal precursor into the first transition metal dichalcogenide to promote growth and can play an important role in the overall growth process. Furthermore, by controlling the content of the alkali metal cholate (e.g., sodium cholate (SC), the formation of large-area, high-quality transition metal dichalcogenide heterostructures can be promoted.

If the content of the alkali metal cholate (e.g., sodium cholate (SC) is less than 0.1 wt %, the growth rate into the first TMC film is very slow, and realizing a large area may be difficult, whereas if it exceeds 1.5 wt %, multiple transition metal crystals may grow simultaneously within the first TMC film, forming a non-uniform and discontinuous film, and quality may decrease.

The pH of the first transition metal precursor solution may be 4.8 to 7.5, preferably 5 to 6, and most preferably 5.1 to 5.5. In this case, if the pH is less than 4.8, particle aggregates are generated due to the aggregation of the first transition metal precursor, making uniform spin coating unachievable, whereas if it exceeds 7.5, a discontinuous film may be formed due to the repulsion between the first transition metal precursor and the substrate, significantly reducing the quality.

The first transition metal precursor may be one or more selected from the group consisting of molybdenum oxide (MoO₃), molybdic acid (H₂MoO₄), sodium hydrogen molybdate (NaHMoO₄), sodium molybdate (Na₂MoO₄), and ammonium orthomolybdate ((NH₄)₂MoO₄), and is preferably molybdenum oxide (MoO₃).

The concentration of the first transition metal precursor may be 2 to 30 mM, preferably 4.5 to 7.5 mM, more preferably 5 to 7 mM, and most preferably 5.5 to 6.5 mM. In this case, if the concentration of the first transition metal precursor is less than 4.5 mM, the spin-coated first transition metal precursor solution may not be coated evenly and may be coated discontinuously, whereas if it exceeds 7.5 mM, the layer thickness of the formed first TMC film increases and multiple pinholes occur, reducing photoluminescence intensity may decrease.

The first spin coating may be performed at 4000 to 6000 rpm for 30 seconds to 3 minutes, preferably at 4500 to 5500 rpm for 40 seconds to 2 minutes, and most preferably at 4800 to 5200 rpm for 30 seconds to 1.2 minutes.

### (C) Step of Performing First CVD Coating of the First Spin-Coated Substrate Under Sulfur and Argon Gas to Form a First Transition Metal Dichalcogenide (TMC) Film

The step (C) may form a first transition metal dichalcogenide (TMC) film by performing first CVD coating of the first spin-coated substrate under sulfur and argon gas. Preferably, the first transition metal dichalcogenide (TMC) film may be a MoS₂ film.

The temperature of the sulfur may be 200 to 300° C., preferably 220 to 280° C., and most preferably 240 to 260° C.

The flow rate of the argon may be 150 to 210 sccm, preferably 160 to 200 sccm, and most preferably 170 to 190 sccm.

The first CVD coating may be performed while maintaining the temperature of the CVD crucible at 700 to 800° C. for 10 to 30 minutes, preferably at 720 to 780° C. for 15 to 25 minutes, and most preferably at 740 to 760° C. for 18 to 22 minutes.

The ramping rate of the sulfur may be 35 to 50° C./min, preferably 38 to 47° C./min, and most preferably 40 to 44° C./min.

In particular, when all the temperature and time conditions for the first CVD coating and the temperature ramping rate condition for sulfur are satisfied, a uniform, continuous, and monolayer first TMC film can be formed. If any of these processes are not satisfied, the formed first TMC film may be non-uniformly or discontinuously formed, and multiple unstable layers, not a single layer, may be randomly formed.

The ramping rate of the first transition metal precursor may be 80 to 120° C./min, preferably 90 to 110° C./min, and most preferably 95 to 105° C./min.

After step (C), the method may further include the step of etching by supplying vapor including water, sulfur, and argon. The etching step may be performed to reduce and fabricate the multi-layer first transition metal dichalcogenide into a monolayer.

### (D) Step of Removing Sodium Particles on the Substrate

The step (D) may be performed by immersing the substrate in water, isopropanol, or a mixture thereof, and through the step (D), sodium particles present on the substrate may be removed.

Removing the sodium particles with water may create a porous TMC film, and removing them with isopropanol may create a pinhole-free TMC film.

If the sodium particles are not completely removed from the substrate in step (D), multiple pinholes may occur or tears may appear in the first TMC film, resulting in significant quality degradation.

After removing the sodium particles in step (D), the substrate may be further washed with nitrogen gas and toluene.

### (E) Step of Forming a Photoresist (PR) Pattern on the Sodium-Removed Substrate

The step (E) may be performed for precise heterostructure formation with the transition metal dichalcogenide (TMC) film.

The step (E) may further include: (E1) applying and curing a photoresist on the substrate; (E2) covering only a portion of the cured photoresist on the substrate with a mask, followed by photoexposure; and (E3) removing the photoexposed photoresist with a developer.

In step (E1), the photoresist (PR) may be applied onto the sodium-removed substrate by spin coating at 4000 to 6000 rpm for 10 seconds to 2 minutes to a thickness of 0.8 to 2 μm, and preferably by spin coating at 4500 to 5500 rpm for 50 seconds to 1.3 minutes to a thickness of 1 to 1.4 μm.

The curing in step (E1) may be performed at 80 to 100° C. for 20 seconds to 2 minutes, preferably at 85 to 95° C. for 50 seconds to 1.5 minutes.

In particular, if either the curing temperature or the curing time in step (E1) does not satisfy the above range, the first TMC film may be damaged during the subsequent reactive ion etching (RIE) process of step (F). That is, the curing is an essential process for forming a TMC film having an in-plane heterostructure.

The photoexposure in step (E2) may be performed at 8 to 13 mW/cm² for 1 to 20 seconds, and preferably at 11 to 12 mW/cm² for 2 to 5 seconds.

(F) Step of Exposing the Hydrophilically Treated Surface of the Region of the Substrate where the PR Pattern is not Formed by Reactive Ion Etching (RIE) of the Substrate on which the PR Pattern is Formed

Step (F) may etch the substrate on which the PR pattern is formed using reactive ion etching (RIE) to expose the hydrophilically treated surface of the region of the substrate where the PR pattern is not formed, serving as a mask for subsequent transition metal dichalcogenide (TMC) formation.

The reactive ion etching (RIE) process may be performed under O₂/CF₄ (25 sccm/25 sccm) flow and 40 to 60 W conditions for 10 seconds to 60 seconds, and preferably under 45 to 55 W conditions for 30 seconds to 50 seconds.

(G) Step of Performing Second Spin Coating of a pH-Controlled Second Transition Metal Precursor Solution Including a Second Transition Metal Precursor and Alkali Metal Cholate (e.g., Sodium Cholate (SC) on the Substrate

The second transition metal precursor solution may include 98.5 to 99.9 wt % of the second transition metal precursor and 0.1 to 1.5 wt % of alkali metal cholate (e.g., sodium cholate (SC), preferably 98.7 to 99.4 wt % of the second transition metal precursor and 0.6 to 1.3 wt % of alkali metal cholate (e.g., sodium cholate (SC), and most preferably 98.9 to 99.1 wt % of the second transition metal precursor and 0.9 to 1.1 wt % of alkali metal cholate (e.g., sodium cholate (SC).

The pH of the second transition metal precursor solution may be 4.8 to 7.5, preferably 5 to 6, and most preferably 5.1 to 5.5.

The second transition metal precursor may be one or more selected from the group consisting of tungsten oxide (WO₃), tungstic acid (H₂WO₄), sodium hydrogen tungstate (NaHWO₄), sodium tungstate (Na₂WO₄), and ammonium orthotungstate ((NH₄)₂WO₄), and is preferably tungsten oxide (WO₃).

The concentration of the second transition metal precursor may be 4.5 to 7.5 mM, preferably 5 to 7 mM, and most preferably 5.5 to 6.5 mM.

The second spin coating may be performed at 4000 to 6000 rpm for 30 seconds to 3 minutes, preferably at 4500 to 5500 rpm for 40 seconds to 2 minutes, and most preferably at 4800 to 5200 rpm for 30 seconds to 1.2 minutes.

### (H) Step of Removing the PR Pattern of the Second Spin-Coated Substrate

The step (H) may be performed to remove the PR pattern of the second spin-coated substrate to more effectively form a heterostructure using the second transition metal precursor solution.

The PR pattern of the second spin-coated substrate may be removed using methyl isobutyl ketone (MIBK). At this time, the step (H) may be performed at 80 to 90° C. for 4 to 8 hours, and preferably at 65 to 75° C. for 5 to 7 hours.

### (I) Step of Performing Second CVD Coating of the PR Pattern-Removed Substrate Under Sulfur and Argon Gas to Form a Second Transition Metal Dichalcogenide (TMC) Film Having a Heterostructure

In the step (I), the temperature of the sulfur may be 200 to 300° C., preferably 220 to 280° C., and most preferably 240 to 260° C.

The flow rate of the argon may be 150 to 210 sccm, preferably 160 to 200 sccm, and most preferably 170 to 190 sccm.

The second CVD coating may be performed while maintaining the temperature of the CVD crucible at 700 to 800° C. for 10 to 30 minutes, and preferably at 720 to 780° C. for 15 to 25 minutes, and most preferably at 740 to 760° C. for 18 to 22 minutes.

The ramping rate of the sulfur may be 35 to 50° C./min, preferably 38 to 47° C./min, and most preferably 40 to 44° C./min.

The ramping rate of the second transition metal precursor may be 80 to 120° C./min, preferably 90 to 110° C./min, and most preferably 95 to 105° C./min.

### (J) Step of Removing Sodium Particles on the Substrate

The step (J) may be performed by immersing the substrate in water, isopropanol, or a mixture thereof, and through the step (J), sodium particles present on the substrate may be removed.

After removing the sodium particles in step (J), the substrate may be further washed with nitrogen gas and toluene.

The TMC produced according to the present invention may contain a small or trace amount of residual alkali metal that has not been removed. In addition, TMC containing a small or trace amount of alkali metal may be presumed to have been manufactured by the method of the present invention.

Preferably, although not explicitly described in the following examples or comparative examples, the method for manufacturing a transition metal dichalcogenide according to the present invention evaluated the morphology, structural stability, and robustness of the in-plane heterostructure by varying the following six conditions.

As a result, unlike other conditions and different numerical ranges, when all the conditions below were satisfied, the morphology of the in-plane heterostructure was uniformly and evenly well formed, with no cracks or partial detachment occurring at all, and the bonding strength with the substrate was robust, resulting in very excellent structural stability.

\textcircled{1} The first transition metal precursor solution includes 98.9 to 99.1 wt % of the first transition metal precursor and 0.9 to 1.1 wt % of sodium cholate (SC), \textcircled{2} the pH of the first and second transition metal precursor solutions is 5.1 to 5.5, respectively, \textcircled{3} the concentration of the first and second transition metal precursors is 5.5 to 6.5 mM, respectively, \textcircled{4} the second transition metal precursor solution includes 98.9 to 99.1 wt % of the second transition metal precursor and 0.9 to 1.1 wt % of sodium cholate (SC), \textcircled{5} the first transition metal dichalcogenide film is molybdenum disulfide (MoS₂), and \textcircled{6} the second transition metal dichalcogenide film may be tungsten disulfide (WS₂).

However, if any one of the six conditions was not satisfied, the morphology of the in-plane heterostructure was non-uniform, and multiple pinholes occurred, resulting in unstable morphological stability. Additionally, some cracks occurred in the transition metal dichalcogenide, and some other parts detached, leading to very poor adhesion to the substrate, and structural stability was also very low.

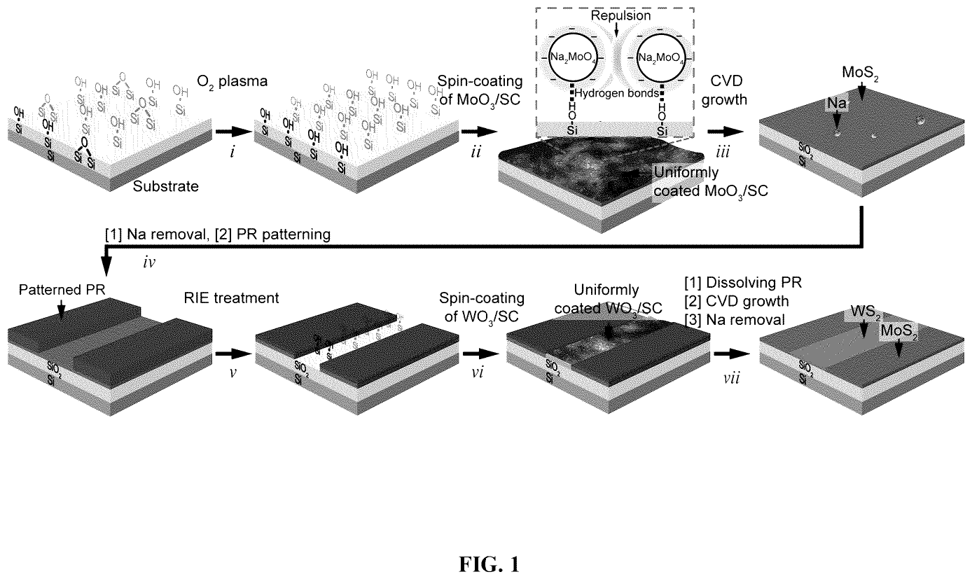

FIG. 1 is a schematic diagram illustrating a method for manufacturing a transition metal chalcogenide having a heterostructure according to the present invention.

Referring to FIG. 1, the transition metal chalcogenide shows each step of generating an in-plane TMC heterostructure compatible with photolithography through repetitive CVD growth. Specifically, FIG. 1 shows the formation of a transition metal dichalcogenide film having an in-plane heterostructure through surface hydrophilization Step (Step i), first spin coating Step of the first transition metal precursor solution (Step ii), first TMC growth Step (Step iii), photoresist patterning Step (Step iv), reactive ion etching (RIE) Step (Step v), second spin coating of the second transition metal precursor solution (Step vi), PR removal, CVD growth, Na particle removal Step (Step vii).

The present invention also provides a transition metal dichalcogenide having a heterostructure, comprising: a substrate; and a transition metal dichalcogenide formed on the substrate, wherein the transition metal dichalcogenide is composed of a heterostructure in which a second transition metal dichalcogenide is inserted in a pattern into a first transition metal dichalcogenide in the plane of the substrate.

The area of the first transition metal dichalcogenide may be larger than the area of the second transition metal dichalcogenide.

Furthermore, the present invention provides a photoelectric device including the transition metal dichalcogenide having a heterostructure of the present invention.

Furthermore, the present invention provides an optoelectronic device including the photoelectric device of the present invention.

Hereinafter, the present invention will be described in more detail based on the examples, but the present invention is not limited by the following examples.

### Example 1: Manufacture of Transition Metal Dichalcogenide Having a Heterostructure

### (1) Materials

Molybdenum (VI) oxide (purity ≥99.5%), Tungsten (VI) oxide (purity ≥99.9%), Sodium molybdate dihydrate (purity ≥99%), and Sulfur (purity ≥99.5%) were purchased from Merck. SC (purity ≥98%) was obtained from TCI and used as a surfactant, an adhesion promoter for the substrate, and a cation source for the metal oxide precursor. All photolithography chemicals were obtained from MicroChemicals GmbH. DI water (water) exceeding 18 MΩ resistance was used for the MoO₃/SC solution. Argon with a purity of 99.99% or higher was supplied by Donga Gas (Republic of Korea) and used as a carrier gas. Received Si wafers (285 nm thick SiO₂/Si substrate, ShinEtsu) were cut into 1×1 cm² pieces, washed with methanol, acetone, and isopropanol, and then dried with a nitrogen stream.

### (2) Manufacture of Transition Metal Dichalcogenide Having a Heterostructure

### (A) Step: Hydrophilic Treatment of the Substrate Surface

A 285 nm thick SiO₂/Si substrate was treated at 100 W for 7 minutes using oxygen plasma RIE (PS-100, Plasol) or inductively coupled plasma (ICP-RIE, IPS-5000, Sntec) to hydrophilize and remove surface contaminants. Spin coating of the metal precursor solution was performed immediately after O₂-plasma or RIE treatment to minimize moisture adsorption on the hydrophilic SiO₂ surface. For TMC patterning, RIE treatment was performed at 50 W for 40 seconds under O₂/CF₄ flow (25 sccm/25 sccm).

### (B) Step: First Spin Coating Step

A mixed solution was prepared by adding 1 wt % SC and 0.21 mmol MoO₃ to 35 mL of DI water. The mixed solution underwent 1 hour of bath sonication, 2 hours of probe sonication, and 1 hour of centrifugation at 5000 g to obtain approximately 80% supernatant. The obtained supernatant was then filtered using a 0.2 μm syringe filter to obtain the MoO₃/SC solution. The filtered MoO₃/SC solution was placed on the substrate and subjected to first spin coating at 5000 rpm for 1 minute. The pH of the final MoO₃/SC solution was approximately 5.3. Lowering or raising the pH of the MoO₃/SC solution was achieved by adjusting the amount of SC or sodium hydroxide solution, respectively.

(C) Step: First TMC film growth step

All CVD growths were performed using ICVDM.

100 μl of MoO₃/SC (or WO₃/SC) solution was spin-coated onto the O₂ plasma-treated substrate at 5000 rpm for 1 minute, and then placed in a mini CVD crucible. 1000 mg of sulfur was placed in an alumina crucible and then placed in the sulfur tube furnace. Parameters for the mini CVD, charge-coupled device (CCD), chalcogen tube furnace, and flow controller were set. The temperatures of the mini CVD and sulfur were raised to 750° C. and 250° C., respectively, and an argon flow of 180 sccm was maintained. The growth temperature was maintained for 20 minutes, which was reached with a ramp rate of 42° C./min for sulfur and 100° C./min for the MoO₃ precursor. After the growth was finished, the formed first TMC film of MoS₂ was cooled to room temperature.

### (D) Step: Sodium Particle Removal Step

The substrate on which the first TMC film of MoS₂ was formed was immersed in DI (or isopropanol) for 3 minutes to remove sodium particles, and then dried using nitrogen gas. For isopropanol-based removal, the TMC film was immersed in toluene for 20 minutes to remove free sulfur, and then dried with nitrogen gas.

### (E) Step: Photoresist (PR) Pattern Formation Step

PR (AZ GXR 601, 14 cp) was filtered using a 0.45 μm syringe filter to remove large PR polymer particles. The photoresist (PR) was spin-coated onto the sodium-removed substrate at 5000 rpm for 50 seconds to create a film with a thickness of 1.2 μm. It was subsequently cured at 90° C. for 1 minute and then cooled to room temperature. Photoexposure was then carried out using a mask aligner (i-line, Mask Aligner MJB4) at an intensity of 11.5 mW/cm² for 4 seconds. The photoexposed PR with a potential pattern was developed for 90 seconds while stirring using a developer (AZ 300 MIF), and then washed with DI for 2 minutes.

### (F) Step: Reactive Ion Etching (RIE) to Expose the Hydrophilically Treated Surface

A cross-shaped hydrophilic pattern was created on the PR patterned substrate using RIE with a metal mask. The reactive ion etching (RIE) process was performed under O₂/CF₄ (25 sccm/25 sccm) flow and 50 W conditions for 40 seconds.

### (G) Step: Second Spin Coating Step

The WO₃/SC solution was prepared similarly to the MoO₃/SC solution. Since WO₃ has poor water solubility, it was ground with a mortar and pestle for 1 hour to obtain well-dispersed powder. The pH of the final WO₃/SC solution was approximately 5.3. Then, a 6 mM WO₃/SC solution was second spin-coated onto the substrate whose hydrophilically treated surface was exposed by the RIE. The second spin coating was performed under the same conditions as the first spin coating in step (B).

### (H) Step: PR Pattern Removal Step

The PR pattern of the second spin-coated substrate was removed using methyl isobutyl ketone (MIBK).

### (I) Step: Second TMC Film Growth Step

The second TMC film growth was performed identically to step (C), except that the temperature was 850° C. and the time was 20 minutes, thereby forming the second TMC film of WS₂.

### (J) Step: Sodium Particle Removal Step

The substrate on which the second TMC film of WS₂ was formed was immersed in isopropanol for 20 minutes to remove sodium particles, remove free sulfur, and then dried using nitrogen gas. Through this process, an in-plane heterostructure transition metal chalcogenide film was formed in the designated interface region.

### Experimental Example 1: Spin Coating Analysis of Transition Metal Precursor Solution According to pH Change

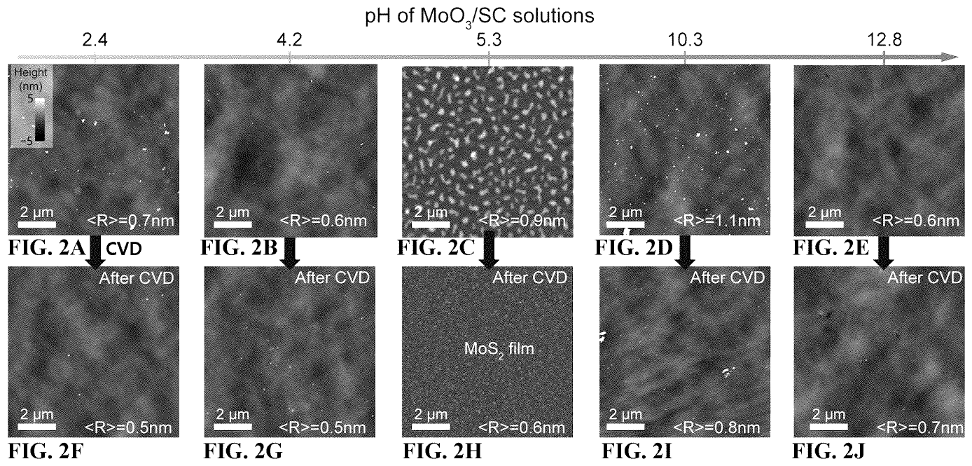

In order to confirm the effect of pH-controlled MoO₃/SC solution used during Spin Coating on the formation of the MoS₂ TMC film in Example 1, the morphology of spin-coated MoO₃/SC solutions at different pH values was confirmed by AFM, and the results are shown in FIG. 2.

The evaluation investigated several pH values (2.4, 4.2, 5.3, 10.3, 12.8), considering the pKa values of molybdic acid, sodium cholate, and silanol groups. Acidification with HCl was avoided to prevent the formation of sodium chloride, which can promote the creation of TMC nanoribbons. Atomic Force Microscopy (AFM) results of the pH-controlled transition metal precursor and subsequent MoS₂ film supported the pKa estimation.

FIG. 2 is an AFM surface morphology image of spin-coated MoO₃/SC solutions at different pH values in Example 1. The height scale is consistently maintained across all images, and (F-J) show corresponding AFM images of the MoS₂ films generated under each pH condition. Referring to (A) to (E) of FIG. 2, the spin-coated MoO₃/SC solution at pH 5.3 exhibited elongated droplet characteristics, whereas particle aggregates appeared in MoO₃/SC solutions at other pH values. The particle aggregates were most numerous and largest at pH 2.4 and pH 10.3, and were observed to decrease in size and number at pH 4.2 and pH 12.8. These observations are consistent with the pKa estimation, indicating that the elongated droplet adsorbates of the MoO₃/SC solution under the slightly acidic condition of pH 5.3 formed hydrogen bonds with the silanol groups while experiencing repulsion with the transition metal precursor.

These results were also consistent with the change in the Root Mean Square roughness (R) with increasing pH, which varied as 0.7, 0.6, 0.9, 1.1, and 0.6 nm. Notably, the 0.6 nm (R) at pH 5.3 was attributed to the average height of discontinuous adsorbates, which was different from the results for other MoO₃/SC solutions.

(F) to (J) of FIG. 2 show the AFM results of MoS₂ grown by CVD from MoO₃/SC solutions at various pH values, where the CVD grown MoO₃/SC solutions at pH 2.4, 4.2, 10.3, and 12.8 formed particle aggregates instead of continuous MoS₂ films, except for pH 5.3. The size and number of these aggregates were consistent with the trends observed in MoO₃/SC solution. Conversely, MoS₂ at pH 5.3 formed a continuous film from the initially discontinuous elongated adsorbates. This was consistent with the change in <R> value with increasing pH, which was measured as 0.5, 0.5, 0.6, 0.8, and 0.7 nm.

In Example 1, a uniform layer was formed during the spin coating of the first transition metal precursor solution by utilizing the pKa values.

During sonication in deionized water (DI), the water-soluble metal oxide is hydrated and converted to a metal acid, and molybdic acid (H₂MoO₄) is converted into sodium hydrogen molybdate (NaHMoO₄) within a narrow pKa range as a polyprotic acid with close pKa values (pKa1=3.61 to 4.0 and pKa2=3.89 to 4.37). Sodium cholate acts as an adhesion promoter and dispersant for MoO₃, and its pKa value is approximately 5.3.

Under neutral conditions, the metal acid exchanged sodium ions twice with SC to form water-soluble metal acid sodium salts (e.g., Na₂MoO₄ and Na₂WO₄) and water-soluble cholic acid. The synthesis process of Na₂MoO₄ is shown in Reaction Scheme 1 below:

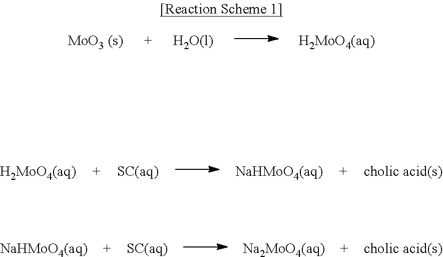

Similar reactions can be expected for tungstic acid (H₂WO₄), which likewise has close pKa values (pKa1=3.5 and pKa2=4.6). Furthermore, as shown in (ii) of FIG. 1, the silanol (Si—OH) group of the hydrophilized SiO₂/Si substrate has a pKa value of approximately 9.8. Accordingly, under slightly acidic conditions, the silanol groups can form strong hydrogen bonds with sodium molybdate (e.g., Si—OH . . . O═Mo), while the transition metal precursors repel each other. These two conditions can promote the uniform spin coating of the transition metal precursors.

### Experimental Example 2: Stability Analysis of MoO₃/SC Solution According to pH Change

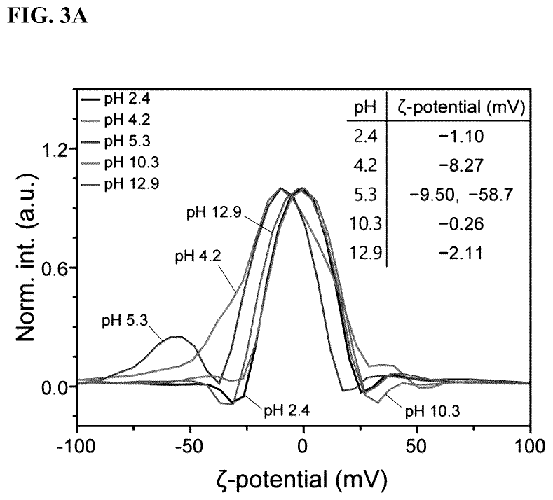

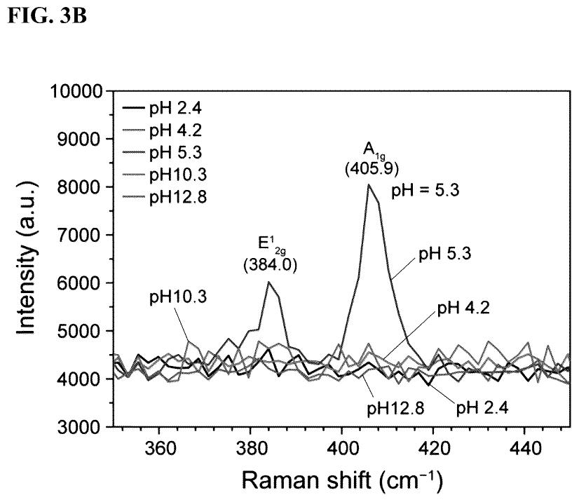

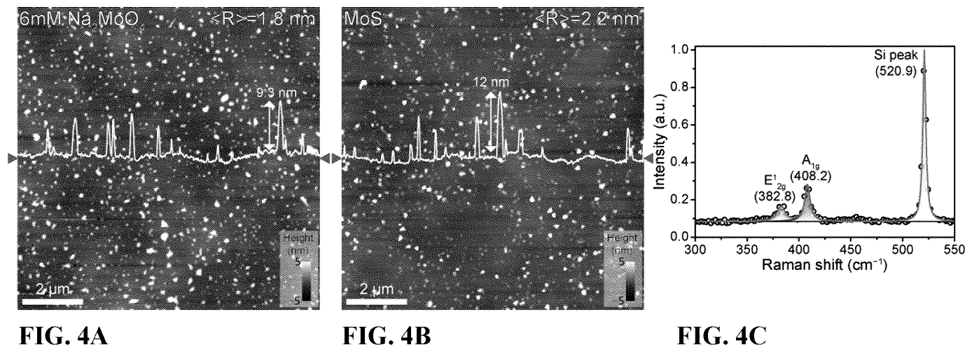

To confirm the stability of the MoO₃/SC solution of Example 1, Zeta (ζ)-potential analysis and Raman spectrum analysis were performed, and the results are shown in FIGS. 3 and 4.

FIG. 3 is a Zeta (ζ)-potential graph (a) and a Raman spectrum graph (b) of CVD grown MoO₃/SC solutions according to pH (2.4, 4.2, 5.3, 10.3, and 12.8) in Example 1. Referring to (A) of FIG. 3, which confirmed the stability of the MoO₃/SC solution measured in a glass cuvette, the MoO₃/SC at pH 4.2 and pH 5.3 showed a peak of −8.3 mV and a bivariant peak of −9.5/−58.7 mV, respectively, indicating anionic surface charge and better stability. Conversely, samples at pH 2.4, pH 10.3, and pH 12.8 showed peaks between −0.26 and −2.1 mV.

Referring to (B) of FIG. 3, a similar trend was observed, with the CVD growth condition proceeding at 750° C. for 20 minutes with sulfur vapor (180 sccm). Raman spectrum results confirmed that only MoS₂ at pH 5.3 exhibited the characteristics of the in-plane E12g and out-of-plane A1g bands of MoS₂ (384.0 and 405.9 cm⁻¹, respectively), and no distinct bands appeared at other pH values. The peak separation of 21.9 cm⁻¹ indicated the formation of bilayer (BL) MoS₂. Based on these results, the MoO₃/SC solution and WO₃/SC solution at pH 5.3 were used in Example 1.

Conversely, a commercially purchased 6 mM sodium molybdate (Na2MoO4) solution without SC showed a pH of approximately 8.4 and was used as a control experiment. FIG. 4 is a spin-coated AFM image of the 6 mM Na2MoO4 solution in Example 1. Referring to FIG. 4, when the 6 mM Na2MoO4 solution was used, it indicated that although the MoS₂ film was formed, the non-moisture-absorbing droplet features were not well formed. This result appears to have occurred due to the absence of SC, which could demonstrate the efficacy of the pH-controlled MoO₃/SC solution for TMC formation.

The uniform formation of the MoS₂ film was greatly influenced by the hydrophilicity of the substrate during the CVD growth process. A hydrophilic substrate allowed for uniform hydrogen bonding with the metal precursor adsorbates. To investigate the effect of substrate hydrophilicity, a control experiment using the exposed portion of one substrate was performed.

### Experimental Example 3: Analysis of the Effect of Substrate Hydrophilicity on MoS₂ Film Formation

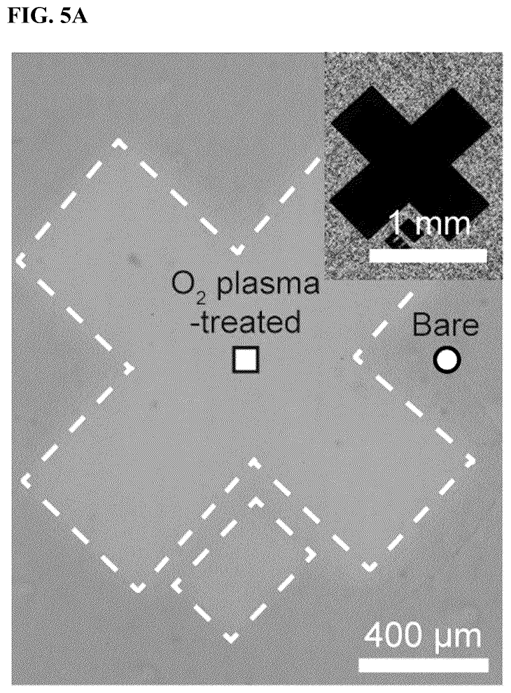

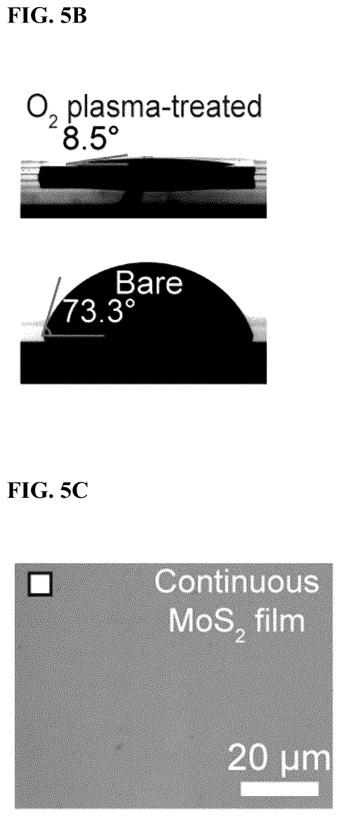

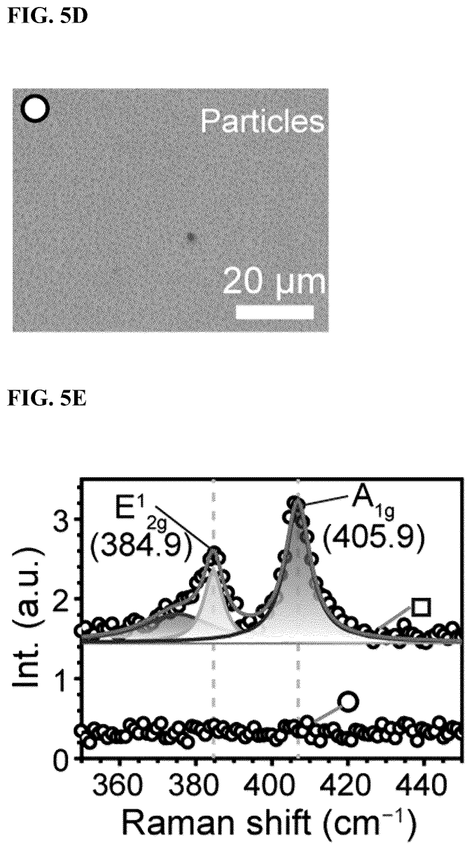

To confirm the effect of hydrophilicity on MoS₂ formation for the MoS₂ film grown by CVD with a hydrophilic pattern in Example 1, optical images, water contact angle, and offset Raman spectrum analyses were performed, and the results are shown in FIG. 5.

FIG. 5 shows an optical image (a) of a MoS₂ film grown by CVD with a hydrophilic pattern, a comparison of water contact angles (b) of an O₂ plasma-treated substrate (top) and an untreated substrate (bottom), water contact angle comparison (b), high-magnification optical images of the O₂ plasma-treated region (C) and the untreated region (D), and an offset Raman spectrum (e) graph of the O₂ plasma-treated region (top) and the untreated region (bottom). The Raman spectrum was decomposed through Lorentz fitting. Experimental data are indicated by empty circles, and the red curve represents the sum of each Lorentz peak.

Referring to (a) of FIG. 5, the optical image shows the formation of a patterned MoS₂ film through CVD growth after O₂ plasma treatment on a stripped substrate using a metal shadow mask (inset figure), wherein the pattern boundaries are not distinct, which was found to be due to reactive ion diffusion occurring at the interface of the shadow metal mask.

Furthermore, in (a) of FIG. 5, the MoS₂ film grown by CVD with the hydrophilic pattern was fabricated by preparing a hydrophilic patterned substrate with cross marks using a metal shadow mask after O₂ plasma treatment, and then spin coating the entire substrate with MoO₃/SC solution, and the O₂ plasma-treated region showed different optical contrast compared to the untreated region.

These results indicated that the hydrophilicity of the substrate plays an important role in the formation and uniformity of the MoS₂ film. This showed that on a highly hydrophilic substrate, the precursor can be effectively adsorbed, improving the growth and quality of the MoS₂ film, whereas on an untreated substrate, adsorption is non-uniform, which can degrade the film quality.

Referring to (b) of FIG. 5, water droplet contact angle measurement results showed that the O₂ plasma-treated substrate exhibited hydrophilicity (8.5°) compared to the untreated substrate (73.3°).

Referring to (c) to (e) of FIG. 5, the untreated region showed isolated particles, while a continuous MoS₂ film was formed in the O₂ plasma-treated region. The corresponding Raman spectrum results confirmed the formation of the MoS₂ film in the patterned region. The O₂ plasma-treated region exhibited the characteristic in-plane E12g and out-of-plane A1g bands at 384.9 and 405.9 cm⁻¹, respectively. The peak separation of 21.0 cm⁻¹ indicated the presence of monolayer (SL) or bilayer (BL) MoS₂. Additionally, the decomposed band at 375.1 cm⁻¹ (purple) corresponds to a defective longitudinal optical (LO) mode. This result shows that a hydrophilic substrate promotes the uniform growth of MoS₂ through consistent spin coating of the MoO₃/SC solution, whereas a hydrophobic substrate resulted in particle aggregation. The hydrophilic areas maintained the spatial pattern from MoO₃/SC spin coating to CVD growth, forming the patterned MoS₂ film.

### Experimental Example 4-1: Analysis of the Effect of Transition Metal Precursor Solution Concentration on MoS₂ Films Promoted by Na Particles

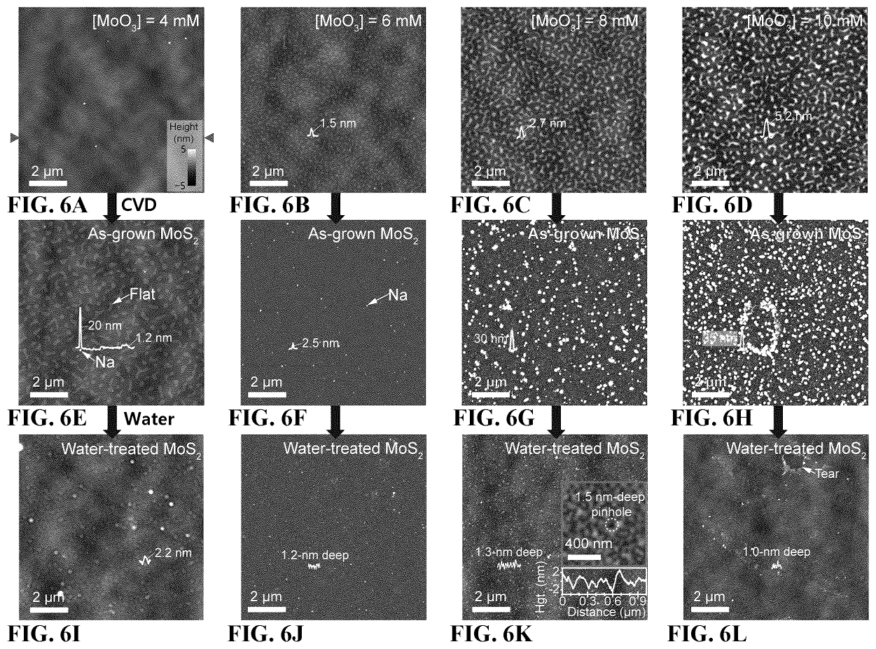

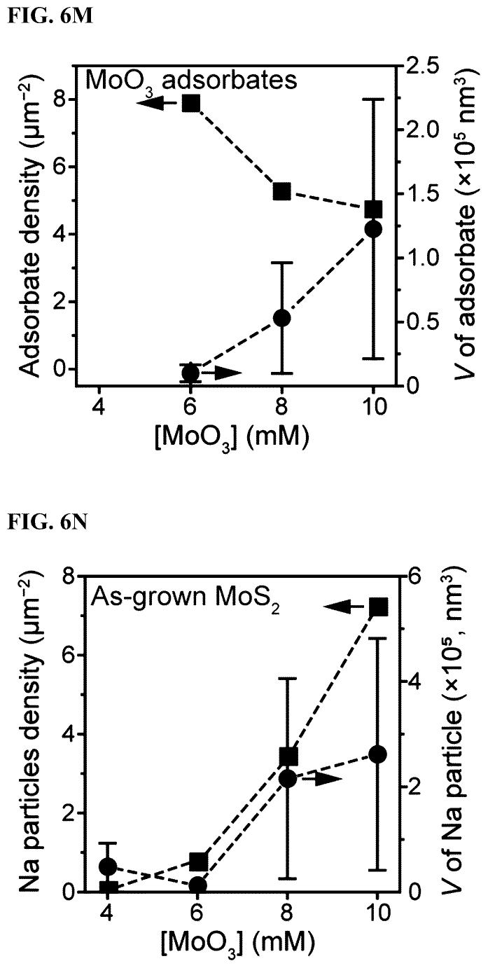

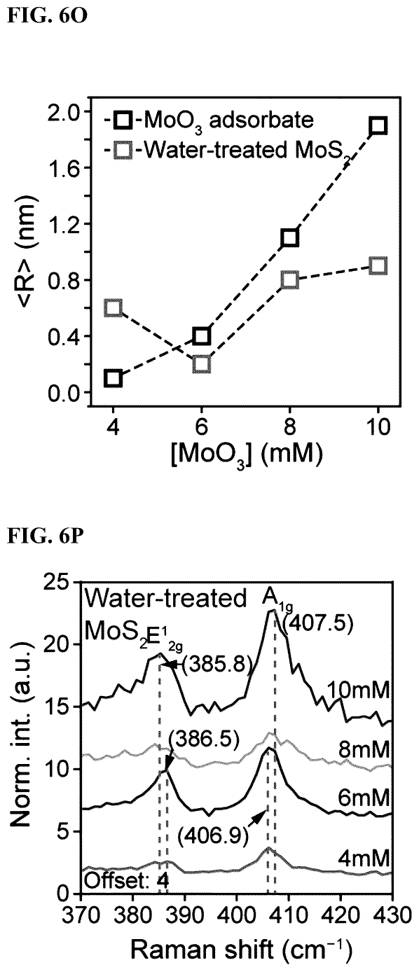

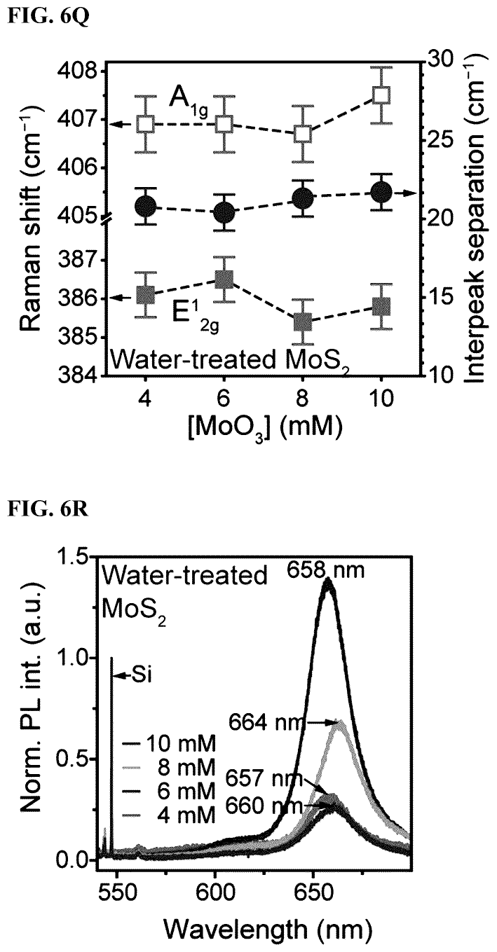

As the MoS₂ film was consistently formed through precursor spin coating on the hydrophilic substrate of Example 1, the effect of the MoO₃/SC solution concentration on the quality and number of layers of MoS₂ was quantitatively investigated. That is, the effect of the concentration of the first transition metal precursor solution on the MoS₂ film promoted by Na particles was confirmed, and the results are shown in FIG. 6.

FIG. 6 shows AFM images of adsorbates in the spin-coated MoO₃/SC solution (A to D), AFM images of grown MoS₂ films (E to H), AFM images of water-treated MoS₂ films at increasing MoO₃ concentrations (4, 6, 8, and 10 mM) (I to L), an adsorbate density (V) graph (M) based on critical height counting at 4 nm according to MoO₃ concentration, a sodium particle density (V) graph (N) according to MoO₃ concentration, the <R> tendency (O) of adsorbates and water-treated MoS₂ films as a function of MoO₃ concentration, the normalized offset Raman spectrum (P) of water-treated MoS₂ films with respect to the 520.8 cm⁻¹ Si band at different MoO₃ concentrations, the positions and peak separation graph (Q) of the E12g and A1g bands according to MoO₃ concentration, and the PL spectrum graph (R) of water-treated MoS₂ films at different MoO₃ concentrations, in Example 1 of the present invention. The height scale is consistent across all images, and white or yellow curves represent the height profiles obtained along pairs of triangles in each figure (A-L). Various MoO₃/SC solution concentrations were prepared by diluting a 20 mM MoO₃/SC mother solution.

Referring to (a) to (d) of FIG. 6, the atomic force microscopy (AFM) surface morphology of spin-coated MoO₃/SC solutions at different concentrations is shown, and the MoO₃/SC solution adsorbates at 4 mM MoO₃ had no distinct features, similar to the supplied substrate. However, at concentrations of 6 mM or higher, discontinuous and elongated adsorbate features appeared, and the height became more pronounced, as indicated by the white curves in each figure. Furthermore, comparison of the average height profiles showed that the adsorbates progressively grew, reaching a maximum of 7 nm.

Excluding the 4 mM MoS₂ film that did not form distinct precursor adsorbates, the adsorbate density decreased as the MoO₃ concentration increased, while the V of single adsorbates increased despite the larger size distribution. This inverse relationship indicated that the intermolecular precursor interaction was stronger than the precursor-substrate interaction, which implied the need to minimize moisture exposure at certain steps.

According to the results in (e) to (h) of FIG. 6, following CVD growth conducted under identical conditions multiple times, the resulting grown MoS₂ film derived from 4 mM initially showed no noticeable features (A), but the grown MoS₂ exhibited discontinuous and elongated island shapes similar to the precursor adsorbates. These island shapes had an average thickness of 1.2 nm, indicating bilayer (BL) MoS₂, and covered approximately 18% of the total area. The arbitrary island shape, rather than the typical triangular or hexagonal MoS₂ morphology, suggested that the growth of MoS₂ did not follow the typical S- or Mo-excess triangular morphology promoted by a few sodium droplets, but instead occurred through multiple nucleation events.

Conversely, samples derived from concentrations of 6 mM or higher formed continuous MoS₂ films. Importantly, sodium particles (indicated by white arrows) originating from the in situ decomposition of sodium molybdate salts produced by the reaction between MoO₃ and SC became more prominent in size and quantity as the solution concentration increased. This was consistent with the result that sodium droplets several tens of nanometers in size precipitate onto the growing lattice of supersaturated MoS₂ sheets, promoting MoS₂ growth. Furthermore, comparison of the height profiles showed that the diameter of sodium particles in the 10 mM film exceeded 30 nm.

(N) of FIG. 6 is a graph showing the density and volume (V) of sodium particles with respect to the initial MoO₃ concentration, where the density and volume increase as the MoO₃ concentration increases, but the volume of the 6 mM sample showed the smallest size. The anomalous behavior observed in the 4 mM adsorbate resulted from the peculiarity of having only four large sodium particles present.

The reactivity of sodium with water is well known, and this reaction generates hydrogen gas, which in turn causes an exothermic reaction with ambient oxygen. Utilizing this, sodium particles were removed from the grown MoS₂ film to create a microporous film. To achieve this, the grown samples were immersed in DI for 3 minutes.

Referring to (i) to (l) of FIG. 6, which are AFM images of water-treated grown MoS₂ films, the water-treated CVD-grown 4 mM film showed several spherical particles with an average height of 1.2 nm, which contrasts with the flat island morphology described above. This was attributed to the spontaneous rolling or folding of MoS₂ sheets in water or alcohol environments. In films of 6 mM or higher, most sodium particles were removed after immersion in water, but many pinholes (˜100 nm diameter, ˜1.5 nm depth) were created during this process, especially numerous in the 8 mM and 10 mM films. This depth indicated that the MoS₂ in these films had two or more layers. Furthermore, comparison of the average height profiles showed frequent and significant height profile variations originating from the pinholes, and the average pinhole depths of the 6-, 8-, and 10-mM films were 1.2, 1.3, and 1.0 nm, respectively. This pinhole formation occurred due to the local thermal decomposition of MoS₂ caused by the exothermic reaction. Furthermore, the 10 mM film also showed a torn MoS₂ film (indicated by a white arrow, L) along with many pinholes. These results suggest that microporosity can be controlled through the generation and size of sodium particles, confirming its usefulness in applications such as water treatment, molecular sieves, and power generation.

Referring to (o) of FIG. 6, in order to understand the characteristics of CVD-grown MoS₂, the <R> values of the adsorbates and the resulting water-washed MoS₂ films were compared, showing that the <R> value of the adsorbates also linearly increased as the MoO₃ concentration increased, which was due to the increasing V of the adsorbates. After water treatment, the MoS₂ film derived from the 6 mM MoO₃/SC solution showed the minimum <R> value, while films of other concentrations showed an increasing trend. The minimum <R> value (˜0.6 nm) was attributed to the initially low number of sodium particles and pinholes within the MoS₂ film. Conversely, the 8 mM and 10 mM samples showed higher <R> values of 0.8 nm and 0.9 nm, respectively, due to the increased number and size of pinholes and the remaining sodium particles.

Referring to (p) of FIG. 6, the Raman spectrum of the water-treated MoS₂ film showed the positions of the E12g and A1g bands close to 386.2 cm⁻¹ and 406.8 cm⁻¹, respectively, which indicated the vibrational characteristics of BL MoS₂. The E12g band showed a low-frequency shift of 0.7 cm⁻¹ as the MoO₃ concentration increased, while the A1g band showed a high-frequency shift of about 0.6 cm⁻¹, indicating a slight increase in the number of MoS₂ layers with increasing MoO₃ concentration.

(Q) of FIG. 6 showed the trend in the positions and peak separation of the E12g and A1g bands according to the MoO₃ concentration. The peak separation increased as the MoO₃ concentration increased, showing the lowest value of 20.4 cm⁻¹ at 6 mM, and the highest value of 21.7 cm⁻¹ in the 10 mM MoS₂ film. However, pinholes could relieve the tensile stress observed in CVD-grown MoS₂, which could cause uncertainty in the layer number based on Raman measurement.

Furthermore, (R) of FIG. 6 showed the Photoluminescence (PL) spectrum results excited at 532 nm, indicating that the 6 mM sample exhibited the highest PL intensity near 660 nm. Films of other concentrations showed relatively low PL intensity and slightly shifted center positions. This tendency suggested that the PL intensity decreased due to the simultaneous effect of film discontinuity caused by pinholes and the increase in the number of layers.

### Experimental Example 4-2: Analysis of the Effect of Na Particle Removal on MoS₂ Films According to Transition Metal Precursor Solution Concentration

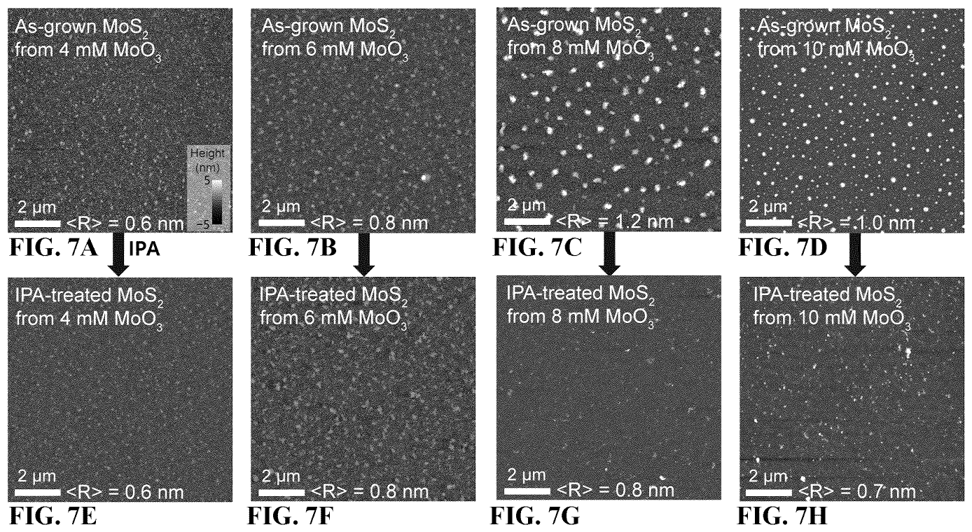

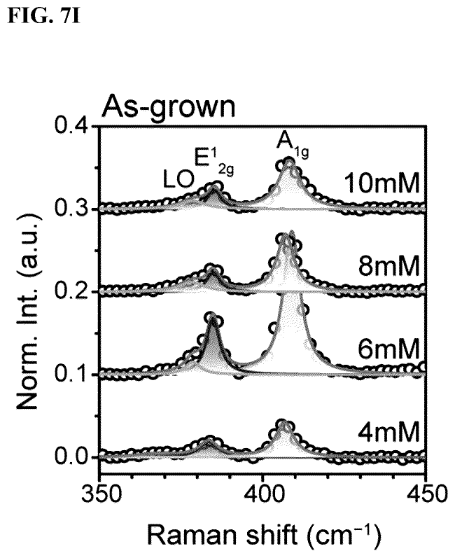

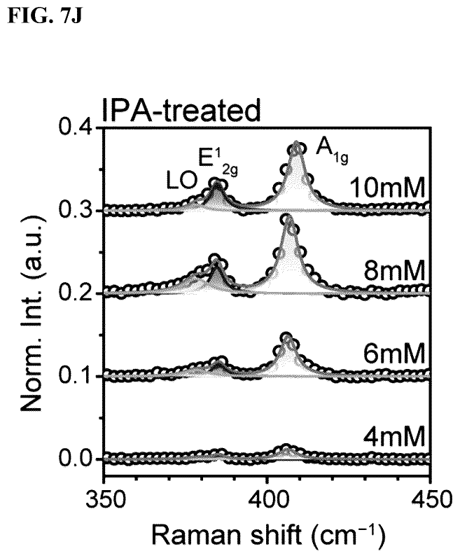

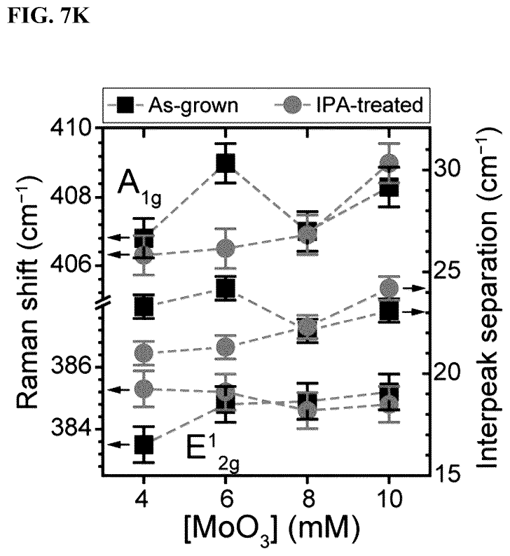

As the MoS₂ film was consistently formed through precursor spin coating on the hydrophilic substrate of Example 1, the effect of Na particle removal on the quality and number of layers of MoS₂ according to the MoO₃/SC solution concentration was quantitatively investigated. The results are shown in FIG. 7.

FIG. 7 shows (A-D) AFM surface morphology images of grown MoS₂ and (E-H) isopropanol (IPA)-treated grown MoS₂ films, (I) the normalized offset Raman spectrum graph of grown MoS₂ films derived from precursor deposits at increasing MoO₃ concentrations (4, 6, 8, 10 mM), (J) the spectrum graph of subsequently IPA-treated MoS₂ films, and (K) the graph of the positions and peak separation of the E12g and A1g bands according to different MoO₃ concentrations, in Example 1.

Referring to (a) to (h) of FIG. 7, pinhole-free MoS₂ films were formed using isopropanol, which reacted more slowly with sodium compared to water. (e) to (h) compared the AFM images of the initially grown MoS₂ films with the results after isopropanol treatment, showing that the initial sodium droplets completely disappeared, and no pinholes were found throughout the images. Additionally, variations in the height profile due to thickness fluctuations were shown, which contrasted with the behavior of water-treated MoS₂ films, indicating a milder reaction between isopropanol and sodium. This pinhole-free surface was also reflected in the <R> trend, showing the lowest value (i.e., 0.6 nm) for the 4 mM film, and a slight increase for higher MoO₃ concentration films (0.8, 0.8, 0.7 nm for the 6, 8, 10 mM films, respectively).

Referring to (i) and (j) of FIG. 7, Raman spectrum analysis of the isopropanol-treated MoS₂ film confirmed that increasing MoO₃ concentration resulted in more layers and increased intensity. (i) shows the silicon band normalized offset Raman spectrum and its deconvolution of the grown MoS₂ film as the MoO₃ concentration increased, and the Raman spectrum showed the E12g and A1g bands and a defect band on the shoulder of E12g.

Furthermore, in (k) of FIG. 7, the graph of the separation between the E12g and A1g bands showed no systematic change positionally. Conversely, a similar Raman spectrum of the isopropanol-treated MoS₂ film showed a systematic change where the E12g and A1g bands separated from each other and the intensity progressively increased as the MoO₃ concentration increased. The peak separation of the 4 mM derived film showed 21.0 cm⁻¹, while 6 mM and higher films progressively increased up to a maximum of 24.2 cm⁻¹, indicating a transition from BL to multilayer. The unsystematic Raman trend of the grown film was found to be caused by the cleaning of partially grown MoS₂ due to sodium particles during isopropanol treatment. Nevertheless, this result indicated that the number of layers could be controlled by adjusting the precursor concentration.

### Experimental Example 5: TEM Analysis

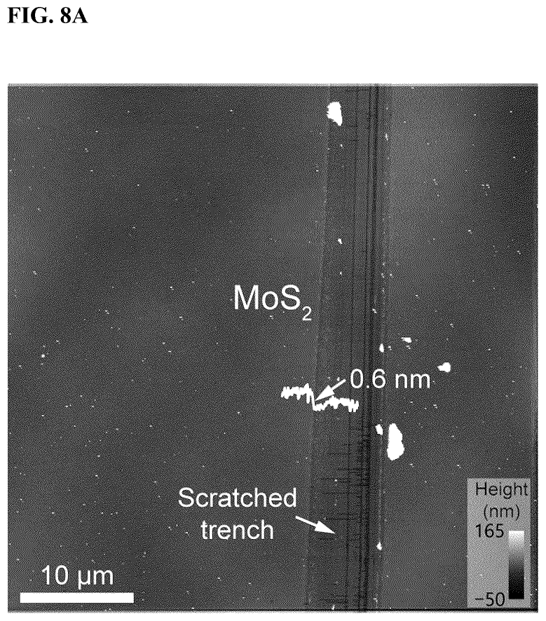

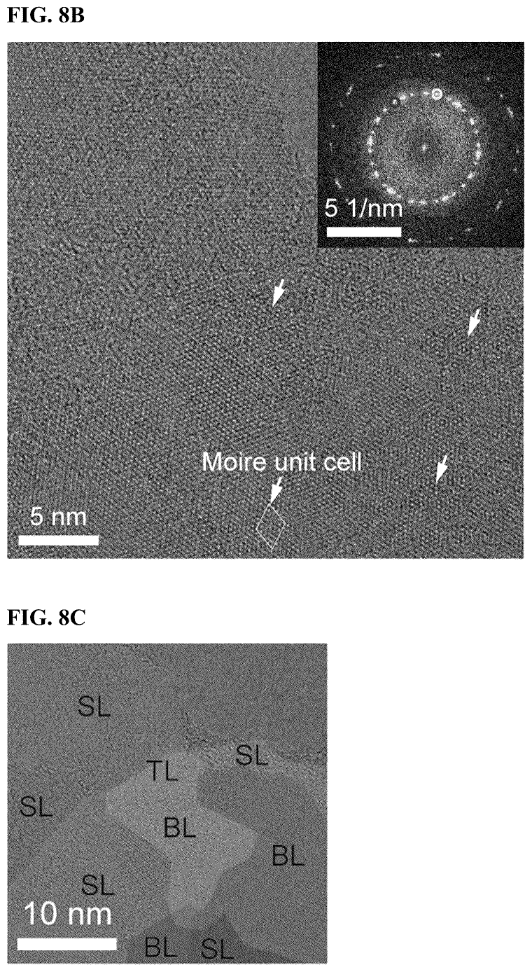

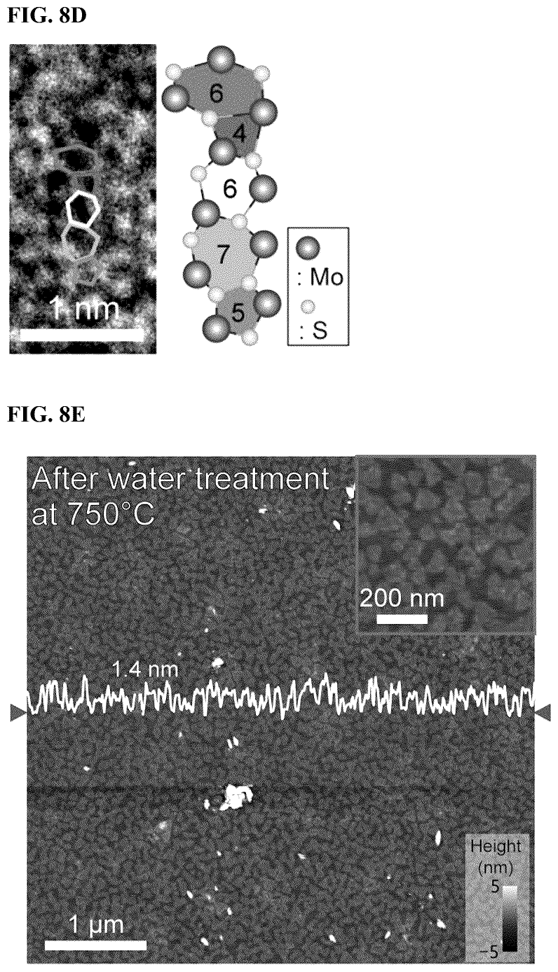

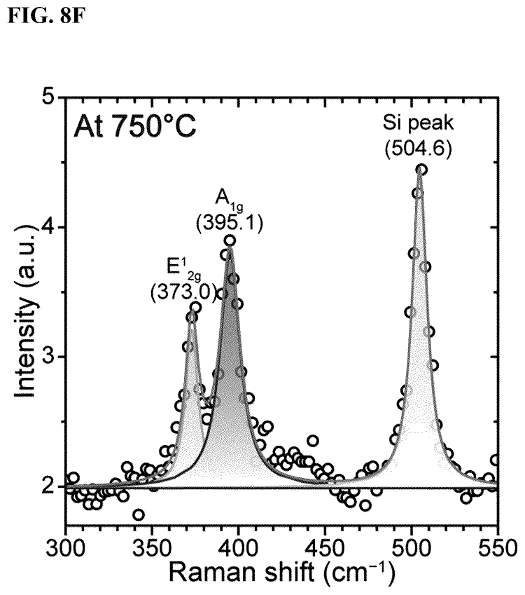

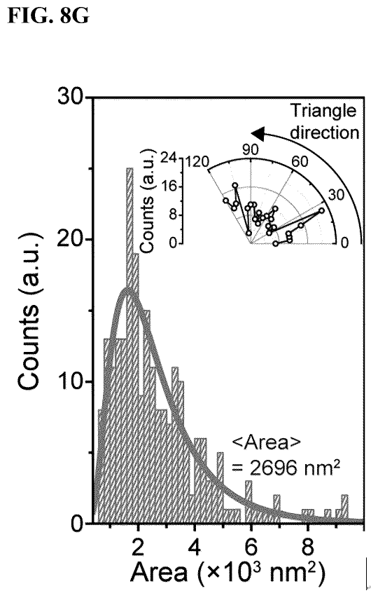

In Example 1, TEM analysis was performed to confirm the effects of polycrystallinity and high-temperature steam and sulfur treatment on the MoS₂ film washed with isopropanol, and the results are shown in FIG. 8.

FIG. 8 shows (A) an AFM image of a scratched MoS₂ film, (B) a HAADF-STEM image of a polycrystalline MoS₂ film where Moire patterns are indicated by white arrows (inset: FFT diffraction pattern showing five sets of hexagonal patterns), (C) a color code representation of MoS₂ polycrystals based on five different crystal directions (identifying BL and TL regions with distinct Moire patterns and representing the SL region), (D) a HAADF-STEM image showing grain boundaries with (6|4)-(7|5) defects, (E) an AFM image showing the formation of triangular BL MoS₂ crystals through steam and sulfur vaporization treatment of the continuous MoS₂ film at 750° C. (inset: close-up view), (F) a real-time Raman spectrum graph of the corresponding film at 750° C., and (G) a size distribution analysis graph (inset: angular distribution of triangular MoS₂) of steam and sulfur-treated triangular MoS₂ crystals, in Example 1.

Referring to (a) of FIG. 8, the AFM image of the scratched MoS₂ film is shown, confirming the formation of single-layer (SL) MoS₂ by confirming a trench depth of about 0.6 nm.

Referring to (b) of FIG. 8, the High-Angle Annular Dark-Field Scanning Transmission Electron Microscopy (HAADF-STEM) image of this film shows Moire pattern regions (indicated by white arrows), representing twisted bilayer (BL) MoS₂ along with the SL region. The Fast Fourier Transform (FFT, inset of 6B) of this image showed five sets of hexagonal diffraction patterns in the 2H phase of MoS₂.

Referring to (c) of FIG. 8, the polycrystalline MoS₂ domains are revealed by masking other diffraction patterns and color coding, showing that SL of tens of nanometers is the dominant layer, and BL and trilayer (TL) domains exist near the SL grain boundary, indicating that SL MoS₂ overlaps to form BL or TL regions.

(d) of FIG. 8 is a HAADF-STEM image showing the grain boundary between SL-SL and its atomic reconstruction, confirming the connection of typical (6|4)-(7|5) defects in MoS₂.

(e) of FIG. 8 shows the AFM morphology of the MoS₂ film exposed to water vapor at 750° C. for 50 seconds while maintaining a continuous sulfur supply, wherein the image shows discontinuous triangular particles with an average height of about 1.4 nm, indicating two layers of MoS₂ (BL), which was different from the initial single layer (SL) MoS₂. This showed that unlike water treatment at room temperature, the morphology of the grown MoS₂ film exposed to water and sulfur vapor at 750° C. within the ICVDM device changed significantly.

(f) of FIG. 8 is the in situ Raman spectrum at 50° C., showing a low-frequency shift of the E12g and A1g bands to 373.0 cm⁻¹ and 395.1 cm⁻¹, respectively, and the Si band also showed a similar shift to 504.6 cm⁻¹. This shift was associated with acoustic mode softening at high temperatures. This morphological reorganization was found to be related to uniform sodium droplets promoting layer formation depending on size. While the long, discontinuous MoS₂ islands observed in the 4 mM film in (e) were grown from multiple nuclei, the reorganized BL MoS₂ appeared to originate from a few Na droplets, which appeared as distinct triangular shapes. As shown in (g) of FIG. 8, these particles had random triangular orientations and an average lateral length of about 79 nm based on an average area of 2696 nm².

### Experimental Example 6: Analysis of in-Plane Heterostructure TMC Compatible with Photolithography and Repetitive CVD Growth

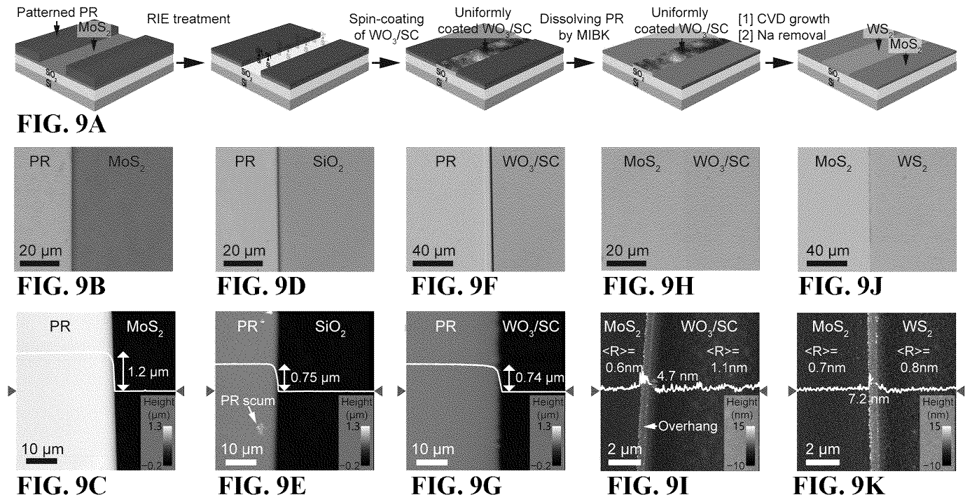

The in-plane heterostructure TMC film compatible with photolithography and repetitive CVD growth of Example 1 was analyzed, and the results are shown in FIG. 9.

FIG. 9 shows (A) a schematic diagram of the process for generating an in-plane heterostructure using photolithography and CVD growth, (B, D, F, H, J) optical images corresponding to each step described in (A), and (C, E, G, I, K) AFM images showing the progress of each step described in (A) (white lines indicate height profiles marked along symmetrical triangle pairs in each figure), in Example 1.

In (a) of FIG. 9, the first step shows the MoS₂ film on the patterned PR developed in the etchant. (b) of FIG. 9 shows the optical image of the patterned PR—MoS₂ film, and (c) of FIG. 9 is the corresponding AFM image, indicating that the PR thickness is 1.2 μm. Subsequently, the entire MoS₂ film underwent RIE treatment to etch the exposed MoS₂ film and PR. Consequently, (d) of FIG. 9 is the resulting optical image, showing the exposed bare SiO₂ floor in the etched MoS₂ region, and (e) of FIG. 9 is the corresponding AFM image, indicating that the PR thickness was reduced to about 750 nm.

Next, the WO₃/SC solution was spin coated. Accordingly, (f) of FIG. 9 is an optical image, showing uniform thin film formation similar to the MoO₃/SC solution. (g) of FIG. 9 is the corresponding AFM image, showing the height topography of the PR thickness of about 740 nm near the PR—WO₃/SC interface. Subsequently, the remaining patterned PR was removed using a solvent without damaging the metal precursor adsorbates. Additional experiments confirmed that acetone and dichloromethane, initially selected for this purpose, successfully removed the patterned PR but left optically visible defects in the film. These defects were found to be due to the high hygroscopicity and volatility of the solvents used. As confirmed in (h) of FIG. 9, MIBK, which has low volatility (boiling point=116° C.) and low hygroscopicity, successfully preserved the uniform WO₃/SC thin film during PR removal.

(i) of FIG. 9 is an AFM image, confirming the formation of the MoS₂—WO₃/SC heterostructure, and a WO₃/SC ‘overhang’ with a length of about 700 nm and a thickness of about 4.7 nm was observed at the interface. This overhang, similar to the PR height, was found to be caused by the WO₃/SC spin-coated onto the lateral residue of the PR pattern.

(j) of FIG. 9 is the patterned film undergoing a second CVD growth to convert WO₃ to WS₂ and, after growing at 850° C. for 20 minutes, undergoing isopropanol washing, the optical image indicated the formation of a clean in-plane MoS₂—WS₂ heterostructure without damaging the existing MoS₂ layer. (k) of FIG. 9 is the corresponding AFM image, confirming that a smoother surface was formed compared to the previous <R> values (0.6 nm and 1.1 nm, respectively), with <R> values of 0.7 nm and 0.8 nm for the MoS₂ and WS₂ regions, respectively. Furthermore, the WS₂ overhang maintained its shape while maintaining a slightly increased height of 2.5 nm.

### Experimental Example 7: Analysis of in-Plane Heterostructure TMC Film

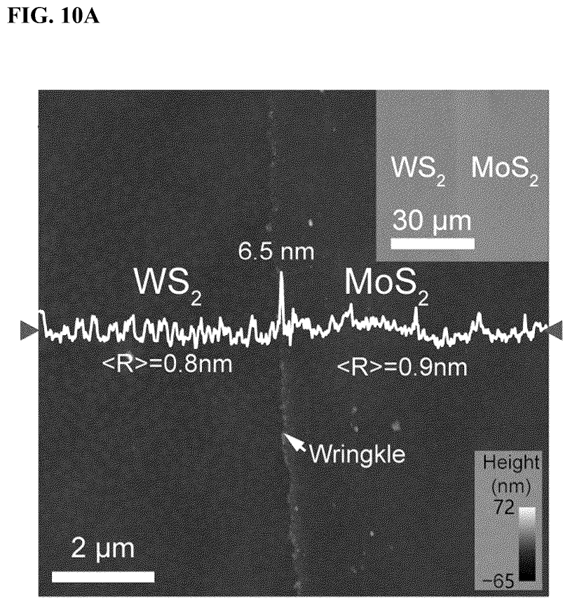

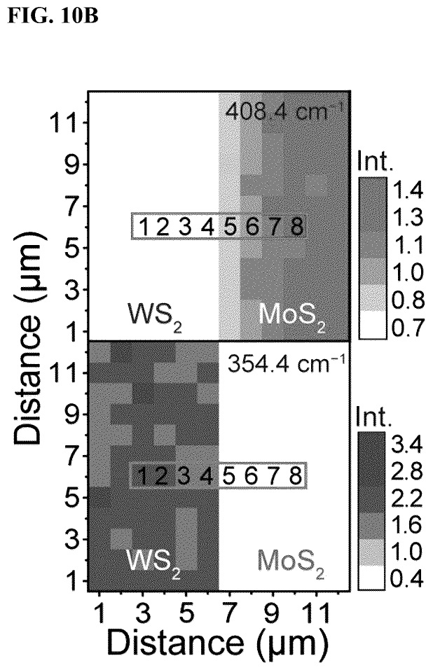

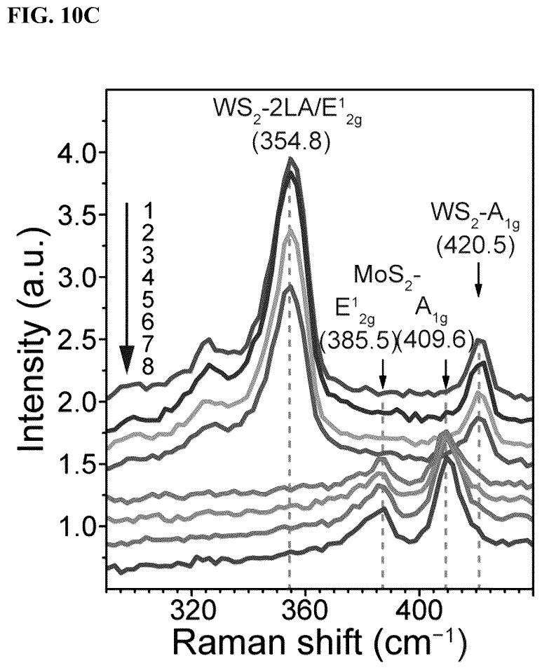

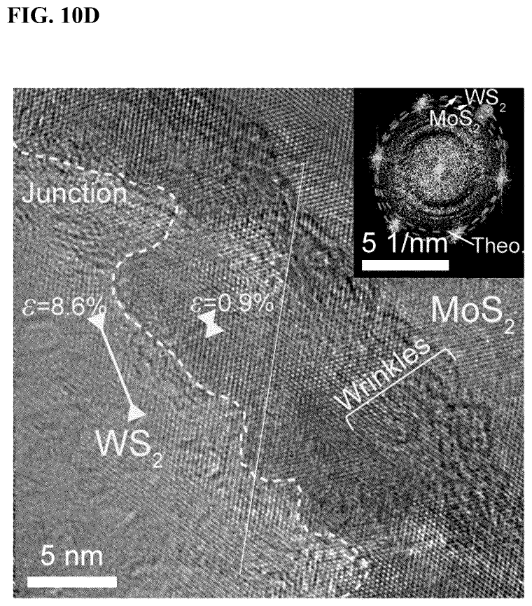

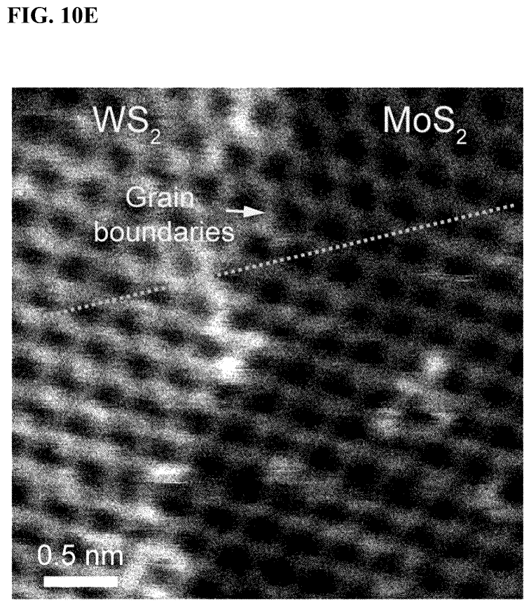

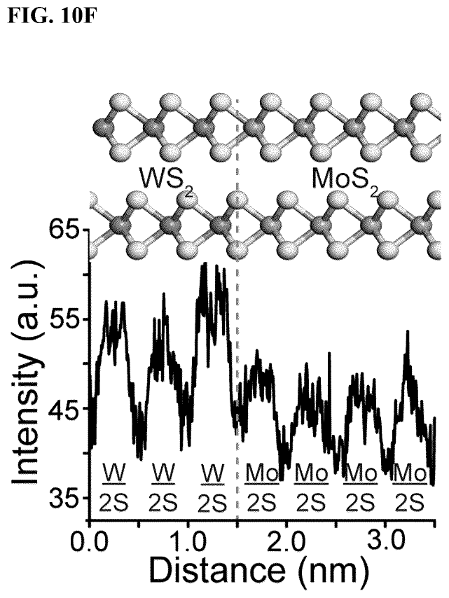

The distinct junction of the heterostructure was confirmed through Raman map and spectrum analysis for the in-plane heterostructure TMC manufactured in Example 1, and the results are shown in FIG. 10.

FIG. 10 shows (A) an AFM surface morphology image of the grain boundary region of the in-plane heterostructure formed through photolithography and repetitive CVD processes (inset: optical image of the heterostructure on the substrate, and the height profile is indicated by white lines marked along opposing triangle pairs in (A)), (B) a Raman intensity map (the upper part shows the 408.4 cm⁻¹ peak corresponding to the A1g band of MoS₂, and the lower part shows the 354.4 cm⁻¹ peak corresponding to the 2LA band of WS₂, pixel size: 1 μm²), (C) a series of Raman spectrum graphs measured across the interface marked in (B), (D) a TEM image near the interface of the heterostructure (the white line highlights the continuous zigzag surface traversing the heterostructure, the two arrows indicate the direction of ϵ, and the inset is the FFT diffraction pattern), (E) a HAADF-STEM image of the interface, and (F) a HAADF-STEM profile measured along the line in (E) (indicating the BL WS₂—MoS₂ heterostructure, where “W|2S” or “Mo|2S” represents the intensity resulting from the overlap of W and 2S, or Mo and 2S, respectively), in Example 1.

(a) of FIG. 10 is the AFM image of the WS₂—MoS₂ interface, showing only a wrinkle with a thickness of 6.5 nm at the junction, and the generated height profile (white trace) further confirmed the formation of the WS₂—MoS₂ in-plane heterostructure, indicating that the <R> values of the WS₂ and MoS₂ layers were 0.8 nm and 0.9 nm, respectively.

(b) of FIG. 10 showed the peak intensity map of 408.4 cm⁻¹ (top) and 354.4 cm⁻¹ (bottom), corresponding to the A1g mode of MoS₂ and the overlapping long acoustic (2LA) and E12g modes of WS₂, respectively. These signals did not overlap spatially, indicating a distinct junction between the WS₂—MoS₂ heterostructures and suggesting that the interface did not involve gradual atomic changes.

(c) of FIG. 10 showed that the Raman spectra measured along the numbered pixels exhibited a distinct vibrational change from the MoS₂ to the WS₂ region, which was in good agreement with the AFM results. Specifically, the Raman spectra of low pixel numbers showed a strong 2LA/E12g mode at 354.8 cm⁻¹ and a less intense A1g mode at 420.5 cm⁻¹, while the spectra of high pixels showed E12g and A1g modes at 385.5 cm⁻¹ and 409.6 cm⁻¹, respectively. A distinct spectral transition was observed between pixels 4 and 5, confirming the presence of each TMC in the designed in-plane WS₂—MoS₂ heterostructure.

(d) of FIG. 10 showed the junction morphology according to the growth order of the heterostructure based on TEM results, showing a TEM image where the WS₂ region was joined with the MoS₂ region, appearing bright due to the high atomic number of WS₂. Along the interface, the Mo- or W-terminated zigzag crystal direction (white line) persists from the MoS₂ region to the wrinkle region, the grain boundary, and the WS₂ region, indicating epitaxial growth of the heterostructure. The FFT diffraction pattern (inset) of the entire image showed two strong elliptical hexagonal lattice patterns, marked by red and cyan circles for MoS₂ and WS₂, respectively, merged together, indicating the epitaxial nature of the heterostructure. Upon closer inspection, a weak hexagonal pattern (purple) rotated approximately 30° relative to the strong pattern appeared, which originated from the localized MoS₂ in the region enclosed by the purple dashed line in (d) of FIG. 10. The measured inverse distances (about 3.65 and 3.96 nm-1) of the inner and outer spots originated from the [1100] plane, indicating that the lattice constant a for the most reduced MoS₂ and WS₂ axes were 3.18 Å and 2.92 Å, respectively. These a values differed from the predicted values (see green dashed circle; a=3.19 Å and 3.18 Å for MoS₂ and WS₂, respectively, having the same P63/mmc space group). Notably, the elliptical and circular hexagonal patterns were caused by compressive strain ((, see double arrows in (d) of FIG. 10) applied along the interface. The calculated ϵ for MoS₂ and WS₂ based on a were 0.9% and 8.6%, respectively. This suggested that significant ϵ occurred following a smaller a at the junction of the TMC heterostructure.

(e) of FIG. 10 is a HAADF-STEM image, showing that the interface atomic connection forms a smooth junction without vacant defects. (f) of FIG. 10 is the intensity profile of the HAADF-STEM image, further indicating the number of layers on each side. The peaks in the WS₂ region had nearly identical intensity, and each peak was composed of two overlapping sub-peaks of the same intensity (see inset). A similar pattern was observed on the MoS₂ side. This originated from the intensity profile of the BL, indicating the BL or integer multiples thereof of the WS₂—MoS₂ heterostructure.

As described above, the transition metal dichalcogenide having a heterostructure according to Example 1 enabled uniform and even spin coating using the chemical properties of the substrate, the pH of the transition metal precursor, and the sodium-based transition metal precursor solution, forming a reproducible TMC film.

Furthermore, it showed that the concentration of the transition metal precursor directly affects the number of layers of the TMC film, confirming that precise control over the structure is possible. Sodium particles formed by the thermal decomposition of the precursor were removed with water or isopropanol, creating TMC films that were porous or had clean surfaces. At high temperatures, sodium particles reorganized into uniform small particles, leading to a triangular MoS₂ structure. This slightly acidic transition metal precursor solution was compatible with conventional photolithography techniques and repetitive CVD processes, forming a TMC film having an MoS₂—WS₂ heterostructure of a specific size.

What is claimed is:

1. A method for manufacturing a transition metal dichalcogenide having a heterostructure, comprising:
forming a photoresist (PR) pattern on a substrate on which a first transition metal dichalcogenide (TMC) film is formed; and
forming a second transition metal dichalcogenide (TMC) film on the substrate on which the PR pattern is formed.

2. The method for manufacturing a transition metal dichalcogenide having a heterostructure according to claim 1, wherein the step of forming the photoresist (PR) pattern comprises:
(A) hydrophilically treating the substrate surface;
(B) performing first spin coating of a pH-controlled first transition metal precursor solution including a first transition metal precursor and alkali metal cholate on the hydrophilically treated substrate;
(C) performing first CVD coating of the first spin-coated substrate under sulfur and argon gas to form a first transition metal dichalcogenide (TMC) film;
(D) removing alkali metal particles on the substrate; and
(E) forming a photoresist (PR) pattern on the alkali metal-removed substrate.

3. The method for manufacturing a transition metal dichalcogenide having a heterostructure according to claim 1, wherein the step of forming the second transition metal dichalcogenide (TMC) film comprises:
(F) exposing the hydrophilically treated surface of the region of the substrate where the PR pattern is not formed by reactive ion etching (RIE) of the substrate on which the PR pattern is formed;
(G) performing second spin coating of a pH-controlled second transition metal precursor solution including a second transition metal precursor and alkali metal cholate on the substrate;
(H) removing the PR pattern of the second spin-coated substrate;
(I) performing second CVD coating of the PR pattern-removed substrate under sulfur and argon gas to form a second transition metal dichalcogenide (TMC) film; and
(J) removing alkali metal particles on the substrate.

4. The method for manufacturing a transition metal dichalcogenide having a heterostructure according to claim 2, wherein the first transition metal precursor solution includes 98.5 to 99.9 wt % of the first transition metal precursor and 0.1 to 1.5 wt % of alkali metal cholate.

5. The method for manufacturing a transition metal dichalcogenide having a heterostructure according to claim 2, wherein the pH of the first transition metal precursor solution is 4.8 to 7.5.

6. The method for manufacturing a transition metal dichalcogenide having a heterostructure according to claim 2, wherein the first transition metal precursor is one or more selected from the group consisting of molybdenum oxide (MoO₃), molybdic acid (H₂MoO₄), sodium hydrogen molybdate (NaHMoO₄), sodium molybdate (Na₂MoO₄), and ammonium orthomolybdate ((NH₄)₂MoO₄).

7. The method for manufacturing a transition metal dichalcogenide having a heterostructure according to claim 2, wherein the concentration of the first transition metal precursor is 2 to 30 mM.

8. The method for manufacturing a transition metal dichalcogenide having a heterostructure according to claim 2, wherein the temperature of the sulfur in steps (C) and (I) is 200 to 300° C., respectively, and the flow rate of the argon is 150 to 210 sccm.

9. The method for manufacturing a transition metal dichalcogenide having a heterostructure according to claim 2, wherein the ramping rate of the sulfur is 35 to 50° C./min, and the ramping rate of the first transition metal precursor and the second transition metal precursor are 80 to 120° C./min, respectively.

10. The method for manufacturing a transition metal dichalcogenide having a heterostructure according to claim 2, further comprising the step of etching by supplying vapor including water, sulfur, and argon, after step (C).

11. The method for manufacturing a transition metal dichalcogenide having a heterostructure according to claim 2, wherein steps (D) and (J) are performed by immersing the substrate in water, isopropanol, or a mixture thereof, respectively.

12. The method for manufacturing a transition metal dichalcogenide having a heterostructure according to claim 2, wherein step (E) further comprises:
(E1) applying and curing a photoresist on the substrate;
(E2) covering only a portion of the cured photoresist on the substrate with a mask, followed by photoexposure; and
(E3) removing the photoexposed photoresist with a developer.

13. The method for manufacturing a transition metal dichalcogenide having a heterostructure according to claim 12,
wherein the application in step (E1) is performed by spin coating the photoresist at 4000 to 6000 rpm for 10 seconds to 2 minutes to a thickness of 0.8 to 2 μm,
the curing in step (E1) is performed at 80 to 100° C. for 20 seconds to 2 minutes, and the photoexposure in step (E2) is performed at 8 to 13 mW/cm² for 1 to 20 seconds.

14. The method for manufacturing a transition metal dichalcogenide having a heterostructure according to claim 3, wherein the reactive ion etching (RIE) process is performed under O₂/CF₄ (25 sccm/25 sccm) flow and 40 to 60 W conditions for 10 seconds to 60 seconds.

15. The method for manufacturing a transition metal dichalcogenide having a heterostructure according to claim 3, wherein the second transition metal precursor solution includes 98.5 to 99.9 wt % of the second transition metal precursor and 0.1 to 1.5 wt % of alkali metal cholate.

16. The method for manufacturing a transition metal dichalcogenide having a heterostructure according to claim 3, wherein the second transition metal precursor is one or more selected from the group consisting of tungsten oxide (WO₃), tungstic acid (H₂WO₄), sodium hydrogen tungstate (NaHWO₄), sodium tungstate (Na₂WO₄), and ammonium orthotungstate ((NH₄)₂WO₄), and the concentration of the second transition metal precursor is 2 to 10 mM.

17. The method for manufacturing a transition metal dichalcogenide having a heterostructure according to claim 3, wherein the pH of the second transition metal precursor solution is 4.8 to 7.5.

18. The method for manufacturing a transition metal dichalcogenide having a heterostructure according to claim 2,
wherein the first transition metal precursor solution includes 98.9 to 99.1 wt % of the first transition metal precursor and 0.9 to 1.1 wt % of sodium cholate (SC),
the pH of the first and second transition metal precursor solutions is 5.1 to 5.5, respectively,
the concentration of the first and second transition metal precursors is 5.5 to 6.5 mM, respectively,
the second transition metal precursor solution includes 98.9 to 99.1 wt % of the second transition metal precursor and 0.9 to 1.1 wt % of sodium cholate (SC),
the first transition metal dichalcogenide film is molybdenum disulfide (MoS₂), and
the second transition metal dichalcogenide film is tungsten disulfide (WS₂).

19. A transition metal dichalcogenide having a heterostructure, comprising:
a substrate; and
a transition metal dichalcogenide formed on the substrate,
wherein the transition metal dichalcogenide is composed of a heterostructure in which a second transition metal dichalcogenide is inserted in a pattern into a first transition metal dichalcogenide in the plane of the substrate.

20. The transition metal dichalcogenide having a heterostructure according to claim 19, wherein the area of the first transition metal dichalcogenide is larger than the area of the second transition metal dichalcogenide.

21. A photoelectric device including the transition metal dichalcogenide having a heterostructure of claim 19.

22. An optoelectronic device including the photoelectric device of claim 21.
